(19) United States
(12) Patent Application Publication
(10) Pub. No.: US 2023/0246632 A1
(43) Pub. Date: Aug. 3, 2023

(54) CRYSTAL OSCILLATION ELEMENT AND CRYSTAL OSCILLATOR

(71) Applicant: Murata Manufacturing Co., Ltd., Nagaokakyo-shi (JP)

(72) Inventor: Toshio NISHIMURA, Nagaokakyo-shi (JP)

(21) Appl. No.: 18/297,720

(22) Filed: Apr. 10, 2023

Related U.S. Application Data
(63) Continuation of application No. PCT/JP2021/037940, filed on Oct. 13, 2021.

(30) Foreign Application Priority Data
Oct. 13, 2020 (JP) 2020-172341

(51) Int. Cl. H03H 9/19; H03H 9/13

(52) U.S. Cl. CPC H03H 9/19; H03H 9/132

(57) ABSTRACT

A crystal oscillation element includes a crystal piece having principal planes defined by a first base axis and a second base axis that intersects the first base axis, and an excitation electrode unit at the principal planes of the crystal piece. The excitation electrode unit has flat plate portions and thick film portions located at electrode ends on the principal planes and that have a thickness larger than that of the flat plate portions. The thick film portion has first protruding portions at the ends in the axis direction of the first base axis, extend in the axis direction of the second base axis and protrude from the flat plate portion, and second protruding portions at the ends in the axis direction of the second base axis, extend in the axis direction of the first base axis and protrude from the flat plate portion.

### CROSS REFERENCE TO RELATED APPLICATIONS

This application is a continuation of PCT Application No. PCT/JP2021/037940, filed Oct. 13, 2021, which claims priority to Japanese Patent Application No. 2020-172341, filed Oct. 13, 2020, the entire contents of each of which are hereby incorporated by reference in their entirety.

### TECHNICAL FIELD

The present invention relates to a crystal oscillation element and a crystal oscillator.

### BACKGROUND

Crystal oscillators with thickness-shear vibrations as their main modes of vibration are widely used as reference signal sources for oscillators and band-pass filters. For example, WO 98/38736 (hereinafter “Patent Document 1”) discloses a configuration in which spurious oscillations, which are vibrations occurring at a frequency other than that of the main vibrations, is reduced by flattening the shape of vibration displacement while changing the mesa thickness ratio of the inverted mesa shape of an excitation electrode.

However, in the conventional technology such as that described in Patent Document 1, it has been desired to further reduce spurious oscillations.

### SUMMARY OF THE INVENTION

Accordingly, it is an object thereof of the present invention to provide a crystal oscillation element and a crystal oscillator that further reduces spurious oscillations.

In an exemplary aspect, a crystal oscillation element is provided that includes a crystal piece having principal planes defined by a first base axis and a second base axis that intersects the first base axis, and an excitation electrode unit at the principal planes of the crystal piece. In the exemplary aspect, when a voltage is applied to the excitation electrode unit, the crystal piece performs thickness-shear vibrations by vibrating in a plane defined by a thickness direction and the first base axis, where the thickness direction is a direction intersecting the principal planes. Moreover, the excitation electrode unit has flat plate portions and thick film portions that are located at electrode ends on the principal planes of the crystal piece and that have a thickness larger than that of the flat plate portions. The thick film portion has first protruding portions that are located at the ends in the axis direction of the first base axis on the principal plane, extend in the axis direction of the second base axis and protrude from the flat plate portion, and second protruding portions that are located at the ends in the axis direction of the second base axis on the principal plane, extend in the axis direction of the first base axis and protrude from the flat plate portion. In addition, a cross-sectional area of the first protruding portion cut in a direction along a plane defined by the first base axis and the thickness direction of the crystal piece is larger than a cross-sectional area of the second protruding portion cut in a direction along a plane defined by the second base axis and the thickness direction of the crystal piece.

In another exemplary aspect, a crystal oscillation element is provided that comprises a crystal piece having principal planes defined by a first base axis and a second base axis that intersects the first base axis, and an excitation electrode unit at the principal planes of the crystal piece. According to the exemplary aspect, when a voltage is applied to the excitation electrode unit, the crystal piece performs thickness-shear vibrations by vibrating in a plane defined by a thickness direction and the first base axis, where the thickness direction is a direction intersecting the principal planes. In addition, the excitation electrode unit has flat plate portions and thick film portions that are located at electrode ends in the directions along the principal planes of the crystal piece and that have a thickness larger than that of the flat plate portions. Moreover, the thick film portion has first protruding portions as protruding portions that are located at the ends in the axis direction of the first base axis on the principal plane and extend in the axis direction of the second base axis.

In yet another exemplary aspect, a crystal oscillation element is provided that includes a crystal piece having principal planes defined by a first base axis and a second base axis that intersects the first base axis, and an excitation electrode unit at the principal planes of the crystal piece. In this aspect, when a voltage is applied to the excitation electrode unit, the crystal piece performs thickness-shear vibrations by vibrating in a plane defined by a thickness direction and the first base axis, where the thickness direction is a direction intersecting the principal planes. Moreover, the excitation electrode unit has flat plate portions and thick film portions that are located at electrode ends in the directions along the principal planes of the crystal piece and that have a thickness larger than that of the flat plate portions, and the thick film portion has second protruding portions as protruding portions that are located at the ends in the axis direction of the second base axis on the principal plane and extend in the axis direction of the first base axis.

In another exemplary aspect, a crystal oscillator is provided that comprises the crystal oscillation element of the abovementioned configuration, a base member on which the crystal oscillation element is mounted, and a lid member joined to the base member to seal the crystal oscillation element.

According to the present invention, spurious oscillations can be further reduced in a configuration of a crystal oscillation element.

### BRIEF DESCRIPTION OF DRAWINGS

FIG. 1 is an exploded perspective view schematically showing the configuration of a crystal oscillator according to a first exemplary embodiment.

FIG. 2 is a cross-sectional view schematically showing the configuration of the crystal oscillator according to the first exemplary embodiment.

FIG. 3 is a diagram for explaining an example of the principal plane defined by the first base axis and the second base axis of the crystal piece.

FIGS. 4(a) and 4(b) are diagrams for explaining an example of the principal plane defined by the first base axis and the second base axis of the crystal piece.

FIG. 5 is a plan view of the crystal oscillation element according to the first exemplary embodiment.

FIG. 6 is a cross-sectional view of the crystal oscillation element according to the first exemplary embodiment.

FIG. 7 is a graph showing an electromechanical coupling constant of the crystal oscillator according to the first exemplary embodiment.

FIG. 8 is a graph showing a vibration characteristic of the crystal oscillation element according to the first exemplary embodiment.

FIGS. 9(a) to 9(d) are graphs showing a vibration characteristic of the crystal oscillation element according to the first exemplary embodiment.

FIG. 10 is a plan view of a crystal oscillation element according to a second exemplary embodiment.

FIG. 11 is a cross-sectional view of the crystal oscillation element according to the second exemplary embodiment.

FIG. 12 is a graph showing an electromechanical coupling constant of the crystal oscillator according to the second exemplary embodiment.

FIG. 13 is a graph showing a vibration characteristic of the crystal oscillation element according to the second exemplary embodiment.

FIG. 14 is a plan view of a crystal oscillation element according to a third exemplary embodiment.

FIG. 15 is a cross-sectional view of the crystal oscillation element according to the third exemplary embodiment.

FIG. 16 is a graph showing an electromechanical coupling constant of the crystal oscillator according to the third exemplary embodiment.

FIG. 17 is a graph showing a vibration characteristic of the crystal oscillation element according to the third exemplary embodiment.

FIG. 18 is a graph showing an electromechanical coupling constant of the crystal oscillator according to the fourth exemplary embodiment.

FIG. 19 is a graph showing a vibration characteristic of the crystal oscillation element according to the fourth exemplary embodiment.

FIG. 20 is a graph showing a vibration characteristic of the crystal oscillation element according to the fourth exemplary embodiment.

FIG. 21 is a graph showing an electromechanical coupling constant of the crystal oscillator according to the fifth exemplary embodiment.

FIG. 22 is a graph showing a vibration characteristic of the crystal oscillation element according to the fifth exemplary embodiment.

FIG. 23 is a graph showing an electromechanical coupling constant of the crystal oscillator according to the sixth exemplary embodiment.

FIG. 24 is a graph showing a vibration characteristic of the crystal oscillation element according to the sixth exemplary embodiment.

FIGS. 25(a) to 25(c) are graphs showing a vibration characteristic of the crystal oscillation element according to the sixth exemplary embodiment.

FIGS. 26(a) to 26(c) are graphs showing a vibration characteristic of the crystal oscillation element according to the sixth exemplary embodiment.

FIG. 27 is a graph showing a vibration characteristic of the crystal oscillation element according to the sixth exemplary embodiment.

FIG. 28 is a graph showing a vibration characteristic of the crystal oscillation element according to the sixth exemplary embodiment.

FIG. 29 is a graph showing a vibration characteristic of the crystal oscillation element according to the sixth exemplary embodiment.

FIG. 30 is a graph showing a vibration characteristic of the crystal oscillation element according to the sixth exemplary embodiment.

FIG. 31 is a graph showing a vibration characteristic of the crystal oscillation element according to the sixth exemplary embodiment.

FIG. 32 is a graph showing a vibration characteristic of the crystal oscillation element according to the sixth exemplary embodiment.

FIG. 33 is a graph showing a vibration characteristic of the crystal oscillation element according to the sixth exemplary embodiment.

FIG. 34 is a graph showing a vibration characteristic of the crystal oscillation element according to the sixth exemplary embodiment.

FIG. 35 is a graph showing a vibration characteristic of the crystal oscillation element according to the sixth exemplary embodiment.

FIG. 36 is a graph showing a vibration characteristic of the crystal oscillation element according to the sixth exemplary embodiment.

FIG. 37 is a graph showing a vibration characteristic of the crystal oscillation element according to the seventh exemplary embodiment.

FIG. 38 is a graph showing a vibration characteristic of the crystal oscillation element according to the seventh exemplary embodiment.

FIG. 39 is a graph showing a vibration characteristic of the crystal oscillation element according to the seventh exemplary embodiment.

FIG. 40 is a graph showing a vibration characteristic of the crystal oscillation element according to the seventh exemplary embodiment.

FIG. 41 is a graph showing a vibration characteristic of the crystal oscillation element according to the seventh exemplary embodiment.

FIG. 42 is a graph showing a vibration characteristic of the crystal oscillation element according to the seventh exemplary embodiment.

FIGS. 43(a) to 43(c) are graphs showing a vibration characteristic of the crystal oscillation element according to the seventh exemplary embodiment.

FIG. 44 is a graph for explaining the functions of the crystal oscillation element.

FIG. 45 is a graph for explaining the functions of the crystal oscillation element.

### DETAILED DESCRIPTION OF EMBODIMENTS

### First Exemplary Embodiment

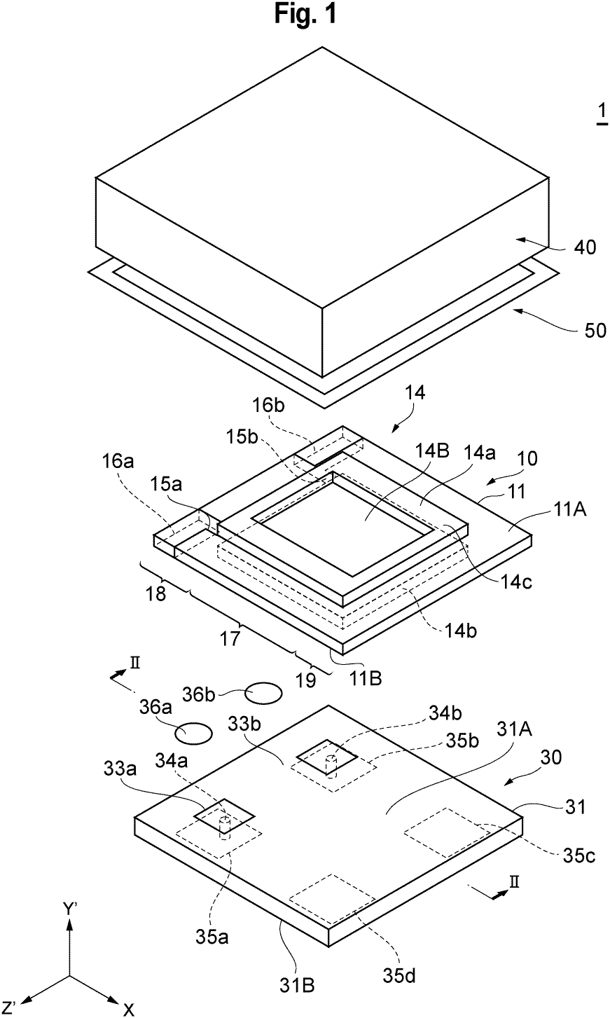

The configuration of the crystal oscillator 1 according to the first exemplary embodiment will be described with reference to FIGS. 1 to 6.

For convenience, an orthogonal coordinate system consisting of X-axis, Y′-axis and Z′-axis is appended to each drawing in order to clarify the relationship between the drawings and to facilitate the understanding of the positional relationship of members. The X-axis, Y′-axis and Z′-axis correspond to each other in each drawing. The X-axis, Y′-axis, and Z′-axis respectively correspond to crystallographic axes of a crystal piece 11, which will be described hereinbelow. The X-axis corresponds to an electrical axis (polar axis), the Y-axis corresponds to a mechanical axis, and the Z-axis corresponds to an optical axis. The Y′-axis and Z′-axis are the axes obtained by rotating the Y-axis and Z-axis about the X-axis from the Y-axis in the direction of the Z-axis through 35 degrees 15 minutes + 1 minute 30 seconds, respectively. For purposes of this disclosure, the X-axis is an example of the first axis, the Y-axis is an example of the second axis, and the Z-axis is an example of the third axis.

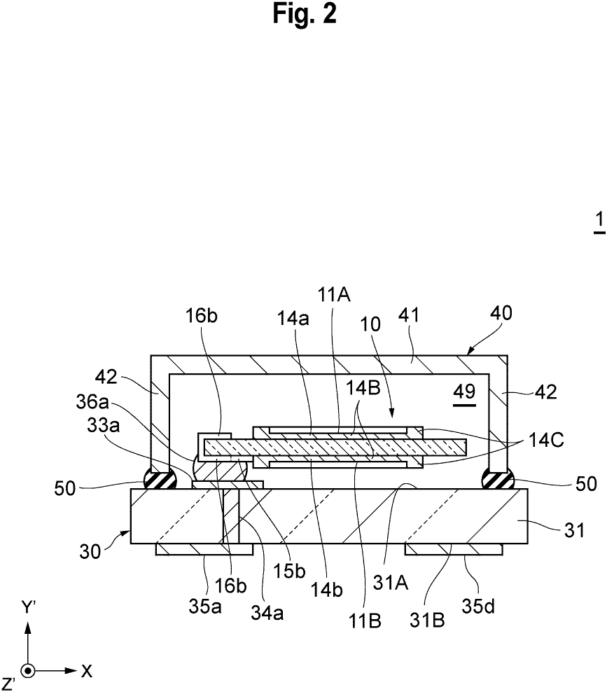

As shown in FIGS. 1 and 2, a crystal oscillator 1 includes a crystal oscillation element 10, a base member 30 (also referred to as a “base”), a lid member 40 (also referred to as a “lid”), and a joining member 50. The crystal oscillation element 10 is provided between the base member 30 and the lid member 40.

The crystal oscillation element 10 includes a flaky crystal piece 11, a first excitation electrode 14a, a second excitation electrode 14b, a first lead-out electrode 15a, a second lead-out electrode 15b, a first connection electrode 16a, and a second connection electrode 16b. In an exemplary aspect, the crystal piece 11 can be formed by etching a crystal substrate (for example, a crystal wafer) obtained by cutting and polishing a synthetic quartz crystal. When a voltage is applied to the first excitation electrode 14a and the second excitation electrode 14b, the crystal piece 11 is configured to perform thickness-shear vibrations by vibrating in a plane defined by a thickness direction and a first base axis of the crystal piece 11, where the thickness direction is a direction that intersects the principal plane of the crystal piece 11.

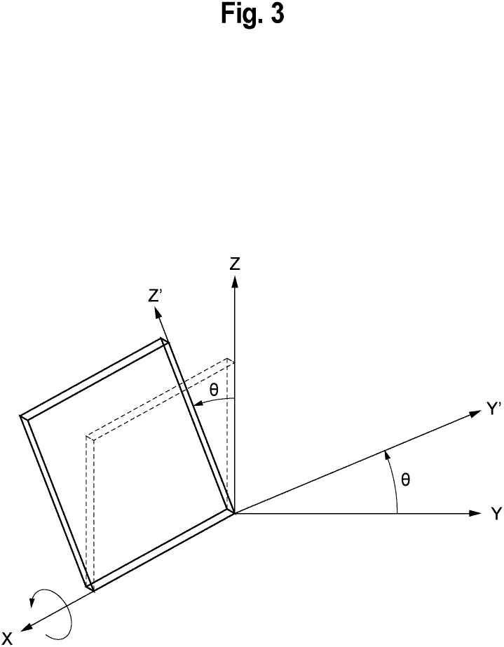

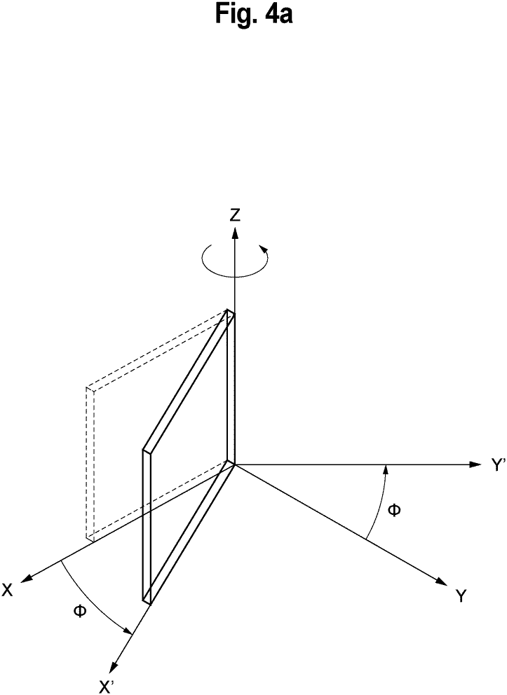

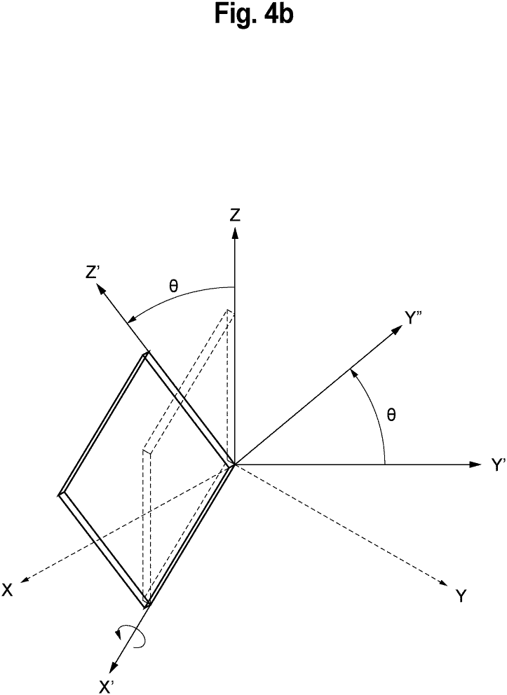

FIGS. 3 and 4(a)-4(b) are diagrams for explaining an example of the principal plane defined by the first base axis and the second base axis of the crystal piece 11. FIGS. 3 and 4(a)-4(b) show examples of cut angles of the crystal piece 11 when the main vibrations of the crystal piece 11 are thickness-shear vibrations, and where the main vibrations of the crystal piece 11 are thickness-shear vibrations. However, it is noted that the exemplary aspects of the present invention may be applied to other cut angles.

In the example shown in FIG. 3, where an axis obtained by tilting a Z axis among X-axis, Y-axis, and Z-axis, which are the crystallographic axes of the crystal piece 11 intersecting with each other, around the X-axis at a predetermined angle θ is defined as a Z′-axis (e.g., a third tilted axis), the X-axis is made to correspond to the first base axis and the Z′-axis is made to correspond to the second base axis. In this case, the first base axis includes, for example, an axis obtained by slightly tilting the X-axis around the Z′-axis. Also, the second base axis includes an axis obtained by tilting the Z-axis around the X-axis at an angle slightly deviating from the predetermined angle. In the example shown in the same figure, the cut angles of the crystal piece 11 include, for example, AT cut, BT cut, and CT cut.

According to the exemplary aspect, in the AT-cut crystal piece 11, for example, the principal plane is a plane parallel to the plane specified by the Z′-axis obtained by tilting the Z-axis at about 35 degrees around the X-axis and the X-axis. In addition, in the AT-cut crystal piece 11, for example, the principal plane may also be a plane parallel to the plane specified by a Z′-axis obtained by tilting the Z-axis around the X-axis at an angle slightly deviating from about 35 degrees and an X′-axis obtained by slightly tilting the X-axis around the Z-axis. The crystal oscillation element 10 using the AT-cut crystal piece 11 has high frequency stability over a wide temperature range. In the BT-cut crystal piece 11, for example, the principal plane is a plane parallel to the plane specified by the Z′-axis obtained by tilting the Z-axis at about -49 degrees around the X-axis and the X axis. In the CT-cut crystal piece 11, for example, the principal plane is a plane parallel to the plane specified by the Z′-axis obtained by tilting the Z-axis at about 38 degrees around the X-axis and the X axis.

In the example shown in FIGS. 4(a)-4(b), where an axis obtained by tilting the X axis, among the X-axis, Y-axis, and Z-axis, which are the crystallographic axes of the crystal piece intersecting with each other, around the Z-axis at a predetermined angle φ is defined as the X′-axis (e.g., a first tilted axis) (see FIG. 4(a)), and an axis obtained by tilting the Z-axis around the X′-axis at a predetermined angle θ is defined as the Z′-axis (e.g., a third tilted axis) (see FIG. 4(b)), the X′-axis is made to correspond to the first base axis and the Z′-axis is made to correspond to the second base axis. In this case, the first base axis includes, for example, an axis obtained by tilting the X-axis around the Z-axis at an angle slightly deviating from the predetermined angle φ. Also, the second base axis includes an axis obtained by tilting the Z-axis around the X′-axis at an angle slightly deviating from the predetermined angle. In the example shown in the same figure, the cut angles of the crystal piece 11 include, for example, an SC cut. In the SC-cut crystal piece 11, for example, a plane parallel to the plane specified by the X′-axis obtained by tilting the X-axis at about 22 degrees around the Z-axis, and the Z′-axis obtained by tilting the Z-axis at about 34 degrees around the X′-axis is the principal plane.

Returning to FIGS. 1 and 2, the AT-cut crystal piece 11 has a plate shape having a long side direction in which the long side extends parallel to the X-axis direction, a short side direction in which the short side extends parallel to the Z′-axis direction, and a thickness direction in which the thickness extends parallel to the Y′-axis direction. According to the exemplary aspect, a first principal plane 11A and a second principal plane 11B of the crystal piece 11 are rectangular.

Moreover, the crystal oscillation element 10 has an excitation electrode unit 14. The excitation electrode unit 14 includes, for example, the first excitation electrode 14a and the second excitation electrode 14b. The first excitation electrode 14a is provided at the first principal plane 11A of the crystal piece 11. The second excitation electrode 14b is provided at the second principal plane 11B of the crystal piece 11. The first excitation electrode 14a and the second excitation electrode 14b face each other with the crystal piece 11 interposed therebetween. Moreover, the first excitation electrode 14a and the second excitation electrode 14b have a rectangular shape and are arranged so as to overlap each other in a plan view thereof.

The first excitation electrode 14a and the second excitation electrode 14b have a thick film portion 14C that is located at the electrode ends in the directions along the first principal plane 11A of the crystal piece 11 and has a thickness larger than that of a flat plate portion 14B.

Moreover, the crystal oscillation element 10 has the first lead-out electrode 15a and the second lead-out electrode 15b. The first lead-out electrode 15a is provided at the first principal plane 11A of the crystal piece 11. The first lead-out electrode 15a electrically connects the first excitation electrode 14a and the first connection electrode 16a. The second lead-out electrode 15b is provided at the second principal plane 11B of the crystal piece 11. The second lead-out electrode 15b electrically connects the second excitation electrode 14b and the second connection electrode 16b.

According to this configuration, the first connection electrode 16a extends in the +Z′-axis direction from the end portion of the first lead-out electrode 15a on the -X-axis direction side and is folded back at the end surface of the crystal piece 11 on the +Z′-axis direction side to extend in the -Z′-axis direction along the second principal plane 11B of the crystal piece 11. The first excitation electrode 14a and the base member 30 are electrically connected through the first lead-out electrode 15a and the first connection electrode 16a. The second connection electrode 16b extends in the -Z′-axis direction from the end portion of the second lead-out electrode 15b on the -X-axis direction side and is folded back at the end surface of the crystal piece 11 on the -Z-axis direction side to extend in the +Z′-axis direction along the second principal plane 11B of the crystal piece 11. The second excitation electrode 14b and the base member 30 are electrically connected through the second lead-out electrode 15b and the second connection electrode 16b.

The base member 30 is, for example, a sintered material such as insulating ceramic (e.g., alumina). The crystal oscillation element 10 is mounted on an upper surface 31A of the base member 30. An external circuit board (not shown) is mounted on a lower surface 31B of the base member 30.

The base member 30 includes a first electrode pad 33a, a second electrode pad 33b, a first external electrode 35a, a second external electrode 35b, a third external electrode 35c, a fourth external electrode 35d, and a first conductive holding member 36a, and a second conductive holding member 36b.

The first electrode pad 33a and the second electrode pad 33b are provided on the upper surface of the base member 30 and electrically connected to the crystal oscillation element 10, as shown in FIG. 2, for example.

Moreover, the first external electrode 35a and the second external electrode 35b are provided on the lower surface 31B of the base member 30 and electrically connect the external board (not shown) and the crystal oscillator 1. The third external electrode 35c and the fourth external electrode 35d are dummy electrodes which are provided on the lower surface 31B of the base member 30 and to which no electric signal or the like is input. The first electrode pad 33a is electrically connected to first external electrode 35a by a first through electrode 34a that passes through the base member 30 along the Y′-axis direction. The second electrode pad 33b is electrically connected to the second external electrode 35b by a second through electrode 34b that passes through the base member 30 along the Y′-axis direction.

According to an exemplary aspect, the first conductive holding member 36a and the second conductive holding member 36b are each, for example, a cured product of a conductive adhesive including a thermosetting resin, a photocurable resin, or the like, and the main component of the first conductive holding member 36a and the second conductive holding member 36b is a silicone resin. The first conductive holding member 36a and the second conductive holding member 36b include conductive particles, and for example, metal particles including silver (Ag) are used as the conductive particles.

The first conductive holding member 36a and the second conductive holding member 36b electrically connect the crystal oscillation element 10 and the base member 30. The first conductive holding member 36a joins the first electrode pad 33a and the first connection electrode 16a. The second conductive holding member 36b joins the second electrode pad 33b and the second connection electrode 16b. The first conductive holding member 36a and the second conductive holding member 36b hold the crystal oscillation element 10 spaced apart from the base member 30 so that the crystal oscillation element 10 could be excited.

The lid member 40 is joined to the base member 30 and forms an internal space 49 between itself and the base member 30. Moreover, the crystal oscillation element 10 is accommodated in the internal space 49. Although the material of the lid member 40 is not particularly limited, it can be made of, for example, a conductive material such as metal. By making the lid member 40 of a conductive material, the entry and exit of electromagnetic waves into the internal space 49 is reduced.

The joining member 50 joins the tip of the side wall portion of the lid member 40 and the upper surface 31A of the base member 30 to seal the internal space 49. The joining member 50 desirably has high gas barrier properties, and more desirably low moisture permeability. The joining member 50 is, for example, a cured product of an adhesive mainly composed of an epoxy resin. The resin-based adhesive that forms the joining member 50 may include, for example, a vinyl compound, an acrylic compound, a urethane compound, a silicone compound, or the like.

Next, the configuration of the excitation electrode unit 14 of the crystal oscillation element 10 according to the present embodiment will be described with particular focus on the configuration of the thick film portion 14C of the excitation electrode unit 14. In the following description, the thick film portion 14C of the first excitation electrode 14a will be specifically explained for convenience of understanding the description, but the thick film portion of the second excitation electrode 14b also has the same configuration.

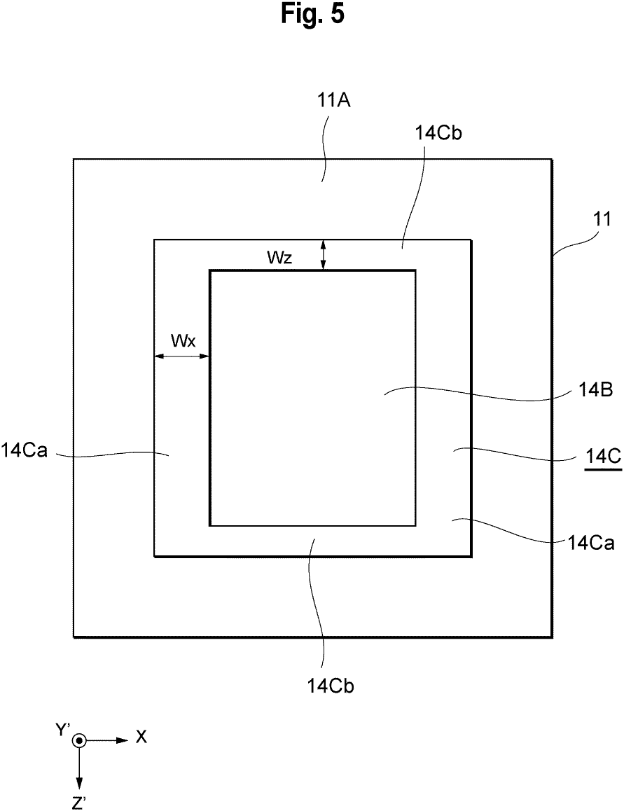

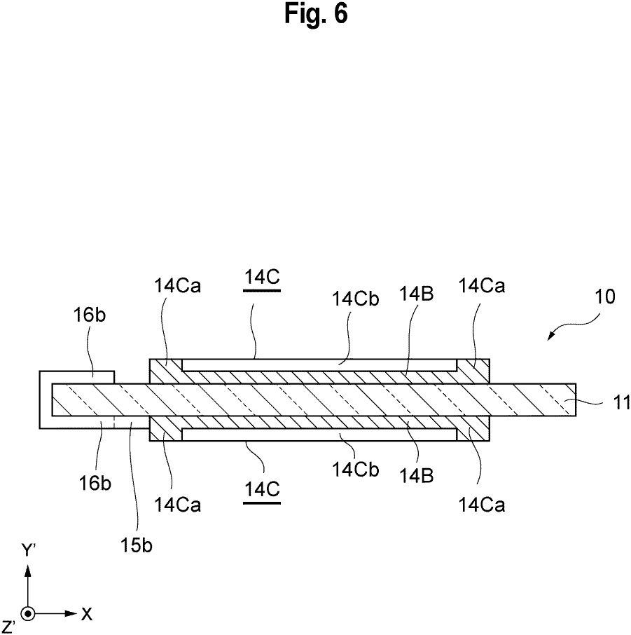

As shown in FIGS. 5 and 6, the first excitation electrode 14a has, for example, the flat plate portion 14B and the thick film portion 14C. The flat plate portion 14B has, for example, a rectangular shape and is provided on the first principal plane of the crystal piece 11. The thick film portion 14C includes first protruding portions 14Ca and second protruding portions 14Cb that protrude (e.g., in the Y′ axis direction) from the upper surface of the flat plate portion 14B. The first protruding portions 14Ca and the second protruding portions 14Cb are made of, for example, the same material as the flat plate portion 14B of the first excitation electrode 14a. However, it is noted that the first protruding portions 14Ca and the second protruding portions 14Cb may be made of a material different from that of the flat plate portion 14B of the first excitation electrode 14a. In this case, the first protruding portions 14Ca and the second protruding portions 14Cb are made of, for example, an insulating material. The first protruding portions 14Ca are located at the ends in the X-axis direction on the first principal plane 11A of the crystal piece 11 and extend in the Z′-axis direction. The first protruding portions 14Ca are located, for example, at both ends in the X-axis direction on the first principal plane 11A of the crystal piece 11 and extend from one end to the other end in the Z′-axis direction on the first principal plane 11A of the crystal piece 11. The second protruding portions 14Cb are located at the ends in the Z′-axis direction on the second principal plane 11B of the crystal piece 11 and extend in the X-axis direction. The second protruding portions 14Cb are located, for example, at both ends in the Z′-axis direction on the second principal plane 11B of the crystal piece 11 and extend from one end to the other end in the X-axis direction on the second principal plane 11B of the crystal piece 11. The width Wx of the first protruding portion 14Ca is larger than the width Wz of the second protruding portion 14Cb.

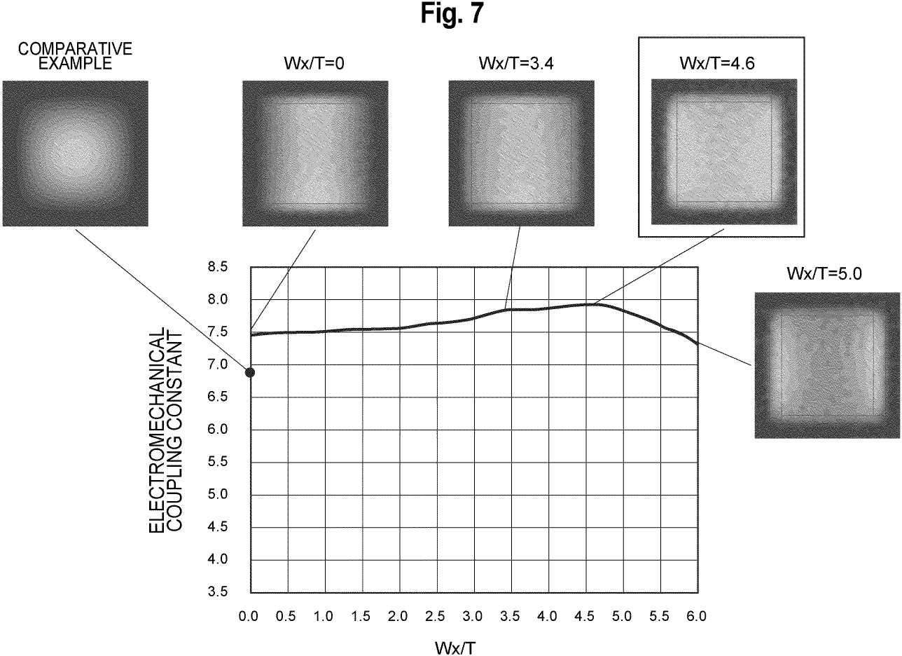

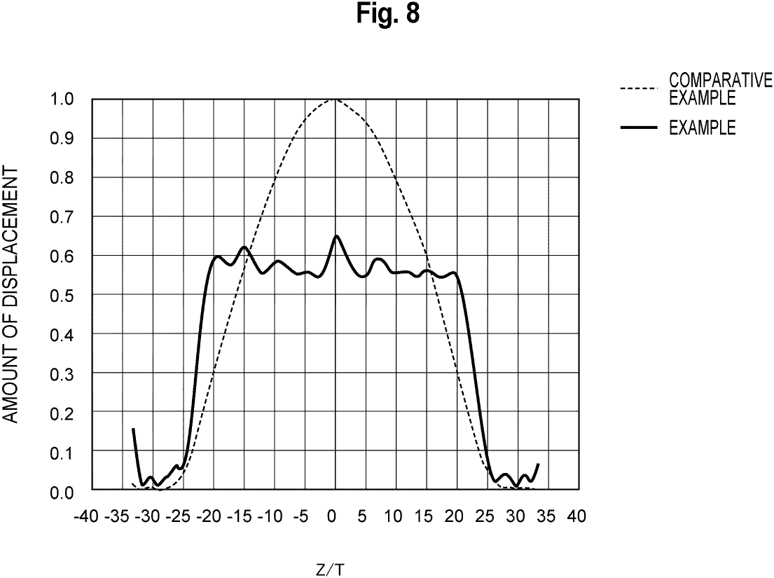

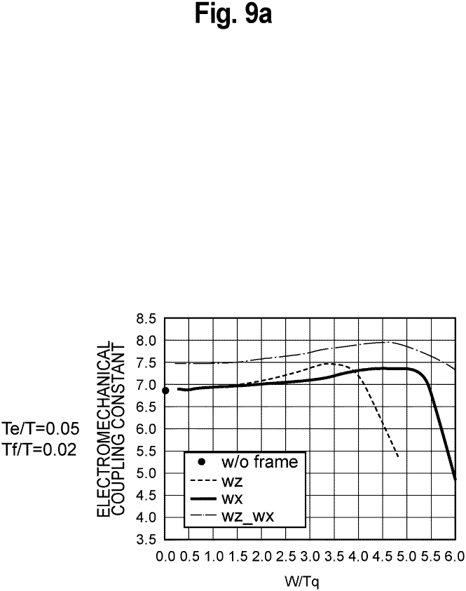

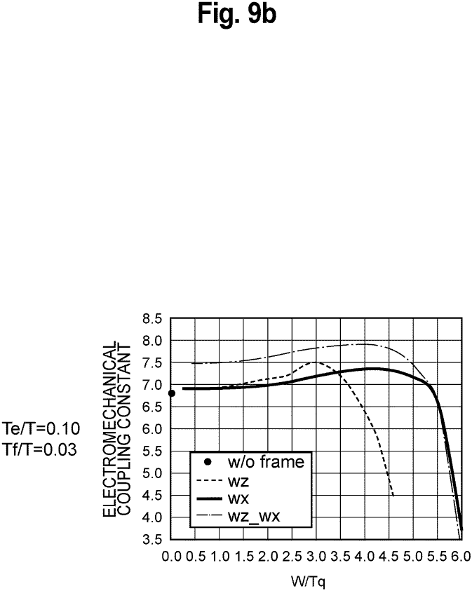

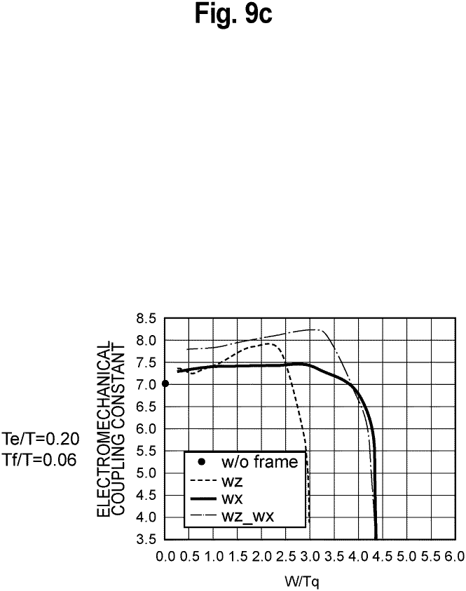

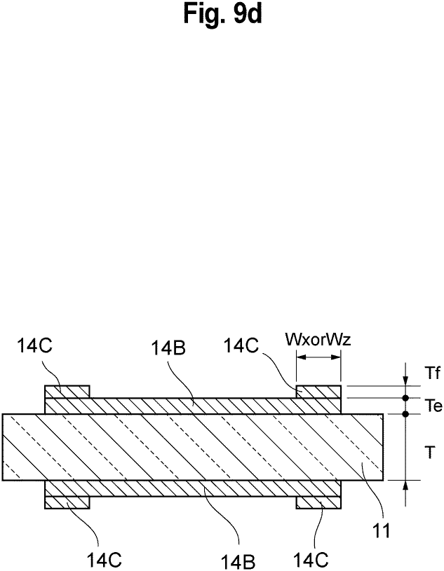

Next, the functions of the crystal oscillator 1 according to the present embodiment will be described with reference to FIGS. 7 to 9. FIGS. 7 and 8 show vibration characteristics of the crystal oscillation element 10 predicted using a simulation model of the crystal oscillator 1 according to the present embodiment. In the simulation model of the crystal oscillator 1, aluminum is set as the material of the excitation electrode unit 14. Further, in the simulation model of the crystal oscillator 1, when a voltage is applied to the excitation electrode unit 14, the crystal piece 11 performs thickness-shear vibrations by vibrating in a plane defined by a thickness direction and the first base axis, the thickness direction being a direction intersecting the principal planes. FIG. 7 is a graph showing an electromechanical coupling constant of the crystal oscillation element 10 according to the present embodiment. The electromechanical coupling constant is a coefficient representing the conversion capability between electrical energy and mechanical energy, and the larger the value of this coefficient, the higher the conversion capability between electrical energy and mechanical energy. FIG. 8 is a graph showing a vibration characteristic of the crystal oscillation element 10 according to the present embodiment. The vibration characteristic of the crystal oscillation element 10 indicates the vibration shape of the crystal oscillation element 10 during the thickness-shear vibration. FIG. 9 is a graph showing the vibration characteristic of the crystal oscillation element 10 according to the present embodiment while changing various parameters relating to the crystal oscillation element 10.

In the example shown in FIG. 7, the width Wz of the second protruding portion 14Cb is fixed at “3.4”, and the transition of a change in the electromechanical coupling constant of the crystal oscillation element 10 when the width Wx of the first protruding portion 14Ca is changed is shown. In the example shown in the same figure, the vertical axis represents the electromechanical coupling constant, and the horizontal axis represents the ratio of the width Wx of the first protruding portion 14Ca to the thickness T of the crystal piece 11. In this example, the value of the electromechanical coupling constant is “6.8” in a comparative example corresponding to the case where the excitation electrode unit 14 is not provided with the first protruding portions 14Ca and the second protruding portions 14Cb. Meanwhile, in the example corresponding to the case where the excitation electrode unit 14 is provided with the first protruding portions 14Ca and the second protruding portions 14Cb, in the case in which the ratio of the width Wx of the first protruding portion 14Ca to the thickness T of the crystal piece 11 is increased stepwise from “0.0” to “3.4”, “4.6”, and “5.0”, the value of the electromechanical coupling constant is “7.5” when the ratio is “0”, and the value of the electromechanical coupling constant tends to increase as the ratio increases. The maximum value of the electromechanical coupling constant is “7.9” when the ratio is “4.6”.

That is, when the excitation electrode unit 14 is provided with the first protruding portions 14Ca or the second protruding portions 14Cb, the speed of sound propagating through the excitation electrode unit 14 partially decreases due to a mass load effect. Therefore, during the thickness-shear vibration of the crystal piece 11, the vibration wavelength of the first protruding portions 14Ca or the second protruding portions 14Cb of the excitation electrode unit 14 is relatively shorter than the vibration wavelength of the flat plate portion 14B of the excitation electrode unit 14. The strain that occurs in the first protruding portions 14Ca or the second protruding portions 14Cb of the excitation electrode unit 14 becomes relatively larger than the strain that occurs in the flat plate portion 14B of the excitation electrode unit 14. As a result, during the thickness-shear vibration of the crystal piece 11, strain is concentrated on the first protruding portions 14Ca or the second protruding portions 14Cb of the excitation electrode unit 14, and the strain on the flat plate portion 14B of the excitation electrode unit 14 is relaxed and the amount of displacement becomes uniform, so that the electromechanical coupling constant of the crystal oscillation element 10 increases.

In the example shown in FIG. 7, the crystal oscillation element 10 satisfies the condition that the width Wx of the first protruding portion 14Ca is larger than the width Wz of the second protruding portion 14Cb. That is, since the crystal piece 11 is displaced in the X-axis direction during the thickness-shear vibration of the crystal piece 11, the strain generated in the excitation electrode unit 14 in the X-axis direction is larger than the strain in the Z′-axis direction. Therefore, the optimum value of the width Wx of the first protruding portion 14Ca for relaxing the strain in the X-axis direction is larger than the optimum value of the width Wz of the second protruding portion 14Cb for relaxing the strain in the Z′-axis direction.

In the example shown in FIG. 8, a vibration characteristic of the crystal oscillation element 10 is shown with respect to the case where the ratio of the width Wx of the first protruding portion 14Ca to the thickness T of the crystal piece 11 is set so that the value of the electromechanical coupling constant becomes the maximum value of “7.9” in the example shown in FIG. 7. FIG. 8 is a diagram showing the amount of displacement for each position in the Z-axis direction in the crystal oscillation element 10. In the example shown in FIG. 8, a comparative example corresponding to the case where the first protruding portions 14Ca and the second protruding portions 14Cb are not provided in the crystal oscillation element 10, and an example corresponding to the case where the first protruding portions 14Ca and the second protruding portions 14Cb are provided to the crystal piece 11 under the abovementioned conditions are shown in superposition with each other. As also shown in the example of FIG. 8, the crystal oscillation element 10 of the example has a flat vibration shape during the thickness-shear vibration as compared with the crystal oscillation element 10 of the comparative example, and spurious oscillations, which are vibrations occurring at a frequency other than the main frequency, are advantageously reduced.

In the examples shown in FIGS. 9(a) to 9(c), cases are explained in which the thickness T of the crystal piece 11, the thickness Te of the flat plate portion 14B of the excitation electrode unit 14, and the thickness Tf of the thick film portion 14C of the excitation electrode unit 14 are changed as various parameters related to the crystal oscillation element 10 shown in FIG. 9(d). The thickness Tf corresponds to the protrusion amount of the thick film portion 14C from the flat plate portion 14B of the excitation electrode unit 14. FIG. 9(a) is a graph related to the case where the ratio of the thickness Te of the flat plate portion 14B of the excitation electrode unit 14 to the thickness T of the crystal piece 11 is “0.05” and the ratio of the thickness Tf of the thick film portion 14C of the excitation electrode unit 14 to the thickness T of the crystal piece 11 is “0.02”. FIG. 9(b) is a graph related to the case where the ratio of the thickness Te of the flat plate portion 14B of the excitation electrode unit 14 to the thickness T of the crystal piece 11 is “0.10” and the ratio of the thickness Tf of the thick film portion 14C of the excitation electrode unit 14 to the thickness T of the crystal piece 11 is “0.03”. FIG. 9(c) is a graph related to the case where the ratio of the thickness Te of the flat plate portion 14B of the excitation electrode unit 14 to the thickness T of the crystal piece 11 is “0.20” and the ratio of the thickness Tf of the thick film portion 14C of the excitation electrode unit 14 to the thickness T of the crystal piece 11 is “0.06”. In these examples, when the condition regarding the width Wx of the first protruding portion 14Ca that maximizes the electromechanical coupling constant is compared with the condition regarding the width Wz of the second protruding portion 14Cb that maximizes the electromechanical coupling constant, the width Wx of the first protruding portion 14Ca is larger than the width Wz of the second protruding portion 14Cb.

The crystal oscillation element 10 according to the present embodiment includes the crystal piece 11 having the first principal plane 11A and the second principal plane 11B, which are planes parallel to the plane specified by the X-axis and the Z′-axis, where the axes obtained by tilting the Y-axis and the Z-axis, among the X-axis, Y-axis, and Z-axis, which are the crystallographic axes, at a predetermined angle about the X-axis are taken as the Y′-axis and the Z′-axis, and the excitation electrode unit 14 provided at the first principal plane 11A and the second principal plane 11B of the crystal piece 11. In this aspect, when a voltage is applied to the excitation electrode unit 14, the crystal piece 11 performs thickness-shear vibrations by vibrating in a plane defined by a thickness direction and the first base axis, the thickness direction being a direction intersecting the principal planes, the excitation electrode unit 14 has the thick film portions 14C that are located at electrode ends in the directions along the first principal plane 11A and the second principal plane 11B of the crystal piece 11 and have a thickness larger than that of the flat plate portions 14B, the thick film portion 14C has first protruding portions 14Ca that are located at the ends in the axis direction of the X-axis on the first principal plane 11A and the second principal plane 11B and extend in the axis direction of the Z′-axis, and second protruding portions 14Cb that are located at the ends in the axis direction of the Z′-axis on the first principal plane 11A and the second principal plane 11B and extend in the axis direction of the X-axis, and the width Wx of the first protruding portion 14Ca is larger than the width Wz of the second protruding portion 14Cb. In the crystal oscillation element 10, when the width Wx of the first protruding portion 14Ca is larger than the width Wz of the second protruding portion 14Cb, by contrast with the case where the width Wx of the first protruding portion 14Ca is equal to or less than the width Wz of the second protruding portion 14Cb, during the thickness-shear vibration of the crystal piece 11, strain is concentrated on the first protruding portions 14Ca or the second protruding portions 14Cb of the excitation electrode unit 14, and the strain on the flat plate portion 14B of the excitation electrode unit 14 is relaxed and the amount of displacement becomes uniform. Therefore, the value of the electromechanical coupling constant, which corresponds to the efficiency of the piezoelectric effect in the crystal oscillation element 10, increases, so that spurious oscillations, which are vibrations occurring at a frequency other than that of the main vibration, can be reduced.

### Second Exemplary Embodiment

In the second embodiment, descriptions of matters common to the first embodiment will be omitted, and only differences between the embodiments will be described. In particular, similar actions and effects resulting from similar configurations will not be mentioned sequentially for each embodiment.

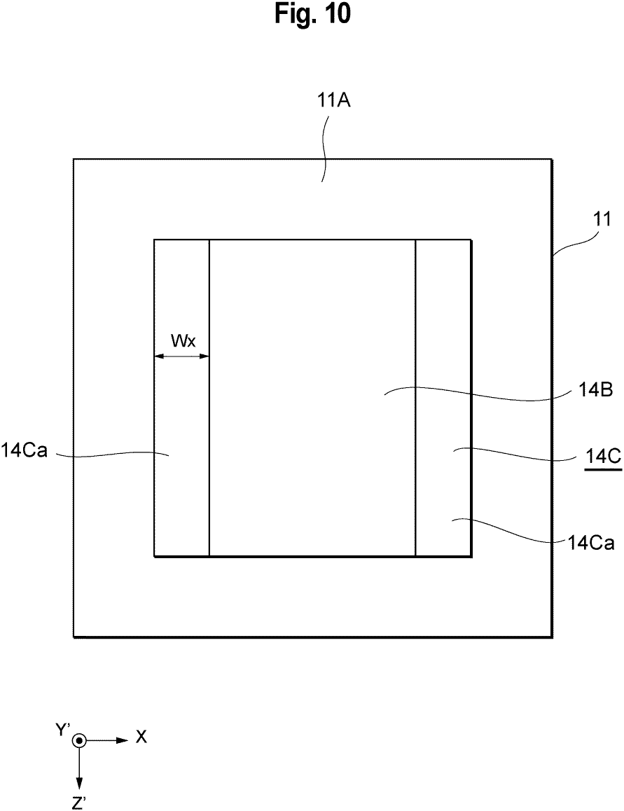

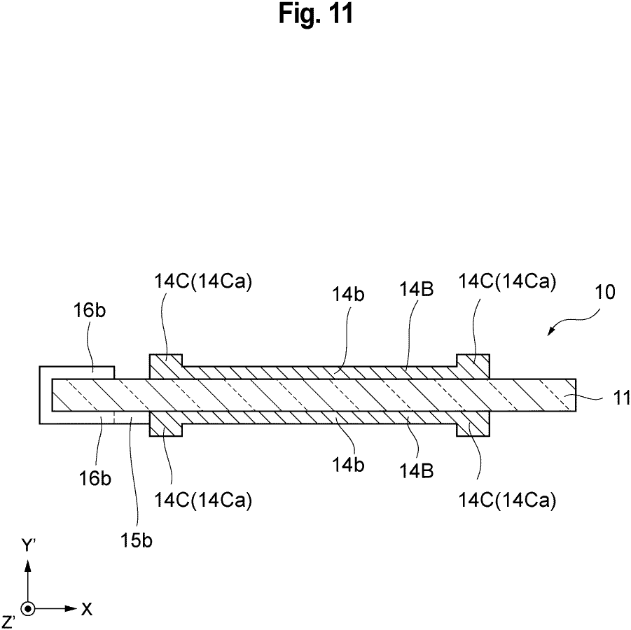

As shown in FIGS. 10 and 11, the first excitation electrode 14a has, for example, the flat plate portion 14B and the thick film portion 14C. The flat plate portion 14B has, for example, a rectangular shape and is provided on the first principal plane 11A of the crystal piece 11. The thick film portion 14C protrudes from the upper surface of the flat plate portion 14B and includes, for example, first protruding portions 14Ca. The first protruding portions 14Ca are located at the ends in the X-axis direction on the first principal plane 11A of the crystal piece 11 and extend in the Z′-axis direction. The first protruding portions 14Ca are located, for example, at both ends in the X-axis direction on the first principal plane 11A of the crystal piece 11 and extend from one end to the other end in the Z′-axis direction on the first principal plane 11A of the crystal piece 11.

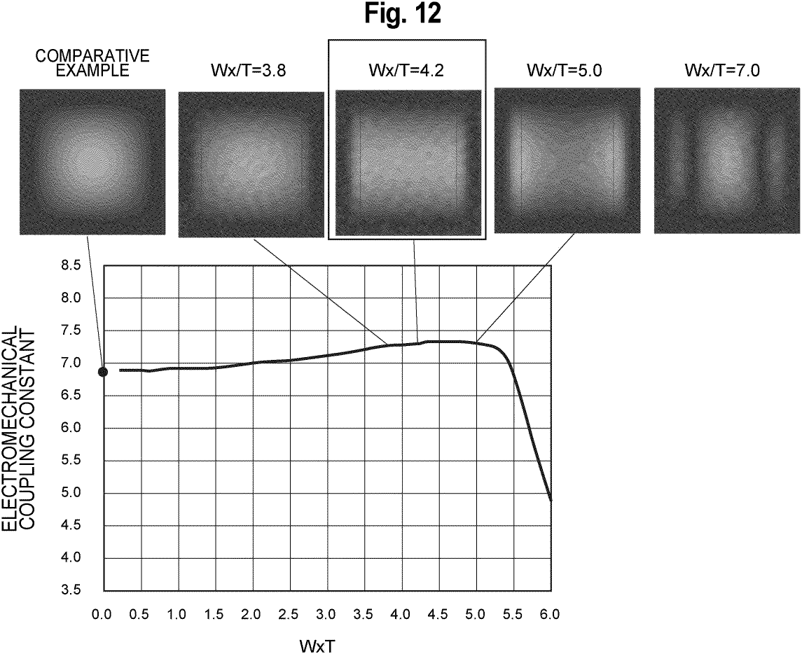

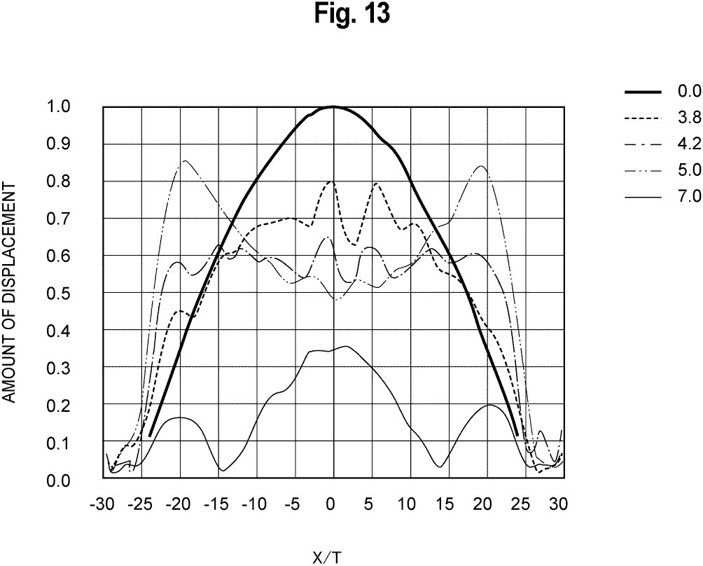

Next, the functions of the crystal oscillator 1 according to the present embodiment will be described with reference to FIGS. 12 and 13. FIGS. 12 and 13 show vibration characteristics of the crystal oscillation element 10 predicted using a simulation model of the crystal oscillator 1 according to the present embodiment. In the simulation model of the crystal oscillator 1, aluminum is set as the material of the excitation electrode unit 14. Further, in the simulation model of the crystal oscillator 1, when a voltage is applied to the excitation electrode unit 14, the crystal piece 11 performs thickness-shear vibrations by vibrating in a plane defined by a thickness direction and the first base axis, the thickness direction being a direction intersecting the principal planes. FIG. 12 is a graph showing an electromechanical coupling constant of the crystal oscillation element 10 according to the present embodiment. FIG. 13 is a graph showing a vibration characteristic of the crystal oscillation element 10 according to the present embodiment. The vibration characteristic of the crystal oscillator 1 indicates the vibration shape of the crystal oscillation element 10 during the thickness-shear vibration.

In the example shown in FIG. 12, the transition of a change in the electromechanical coupling constant of the crystal oscillation element 10 when changing the width Wx of the first protruding portion 14Ca is shown. In the example shown in the same figure, the vertical axis represents the electromechanical coupling constant, and the horizontal axis represents the ratio of the width Wx of the first protruding portion 14Ca to the thickness T of the crystal piece 11. In this example, the value of the electromechanical coupling constant is “6.8” in a comparative example corresponding to the case where the crystal piece 11 is not provided with the first protruding portions 14Ca. Meanwhile, in the example corresponding to the case where the crystal piece 11 is provided with the first protruding portions 14Ca, in the case in which the ratio of the width Wx of the first protruding portion 14Ca to the thickness T of the crystal piece 11 is increased stepwise from “3.8” to “4.2”, “5.0”, and “7.0”, the maximum value of the electromechanical coupling constant is “7.3” when the ratio is “4.2”.

That is, when the excitation electrode unit 14 is provided with the first protruding portions 14Ca, the speed of sound propagating through the excitation electrode unit 14 partially decreases due to a mass load effect. Therefore, during the thickness-shear vibration of the crystal piece 11, the vibration wavelength of the first protruding portions 14Ca of the excitation electrode unit 14 is relatively shorter than the vibration wavelength of the flat plate portion 14B of the excitation electrode unit 14. The strain that occurs in the first protruding portions 14Ca of the excitation electrode unit 14 becomes relatively larger than the strain that occurs in the flat plate portion 14B of the excitation electrode unit 14. As a result, during the thickness-shear vibration of the crystal piece 11, strain is concentrated on the first protruding portions 14Ca of the excitation electrode unit 14, and the strain on the flat plate portion 14B of the excitation electrode unit 14 is relaxed and the amount of displacement becomes uniform, so that the electromechanical coupling constant of the crystal oscillation element 10 increases.

In the example shown in FIG. 13, a vibration characteristic of the crystal oscillation element 10 is shown with respect to the case where the ratio of the width Wx of the first protruding portion 14Ca to the thickness T of the crystal piece 11 is set so that the value of the electromechanical coupling constant becomes the maximum value of “7.3” in the example shown in FIG. 12. FIG. 13 is a diagram showing the amount of displacement for each position in the X-axis direction in the crystal oscillation element 10. In the example shown in FIG. 13, a comparative example corresponding to the case where the first protruding portions 14Ca are not provided to the crystal piece 11, and an example corresponding to the case where the first protruding portions 14Ca are provided to the crystal piece 11 under the abovementioned conditions are shown in superposition with each other. As is also clear from the example shown in FIG. 13, the crystal oscillation element 10 of the example has a flat vibration shape during the thickness-shear vibration as compared with the crystal oscillation element 10 of the comparative example, and spurious oscillations, which are vibrations occurring at a frequency other than the main frequency, are advantageously reduced.

The crystal oscillation element 10 according to the present embodiment includes the crystal piece 11 having the first principal plane 11A and the second principal plane 11B, which are planes parallel to the plane specified by the X-axis and the Z′-axis, where the axes obtained by tilting the Y-axis and the Z-axis, among the X-axis, Y-axis, and Z-axis, which are the crystallographic axes, at a predetermined angle about the X-axis are taken as the Y′-axis and the Z′-axis, and the excitation electrode unit 14 provided at the first principal plane 11A and the second principal plane 11B of the crystal piece 11. In this aspect, when a voltage is applied to the excitation electrode unit 14, the crystal piece 11 performs thickness-shear vibrations by vibrating in a plane defined by a thickness direction and the first base axis, the thickness direction being a direction intersecting the principal planes, the excitation electrode unit 14 has the thick film portions 14C that are located at electrode ends in the directions along the first principal plane 11A and the second principal plane 11B of the crystal piece 11 and have a thickness larger than that of the flat plate portions 14B, and the thick film portion 14C has first protruding portions 14Ca that are located at the ends in the axis direction of the X-axis on the first principal plane 11A and the second principal plane 11B and extend in the axis direction of the Z′-axis. In the crystal oscillation element 10, when the first protruding portions 14Ca are provided, by contrast with the case where the first protruding portions 14Ca are not provided, during the thickness-shear vibration of the crystal piece 11, strain is concentrated on the first protruding portions 14Ca of the excitation electrode unit 14, and the strain on the flat plate portion 14B of the excitation electrode unit 14 is relaxed and the amount of displacement becomes uniform. Therefore, the value of the electromechanical coupling constant, which corresponds to the efficiency of the piezoelectric effect in the crystal oscillation element 10, increases, so that spurious oscillations, which are vibrations occurring at a frequency other than that of the main vibration, can be reduced.

### Third Exemplary Embodiment

In the third embodiment, descriptions of matters common to the first embodiment will be omitted, and only differences between the embodiments will be described. In particular, similar actions and effects resulting from similar configurations will not be mentioned sequentially for each embodiment.

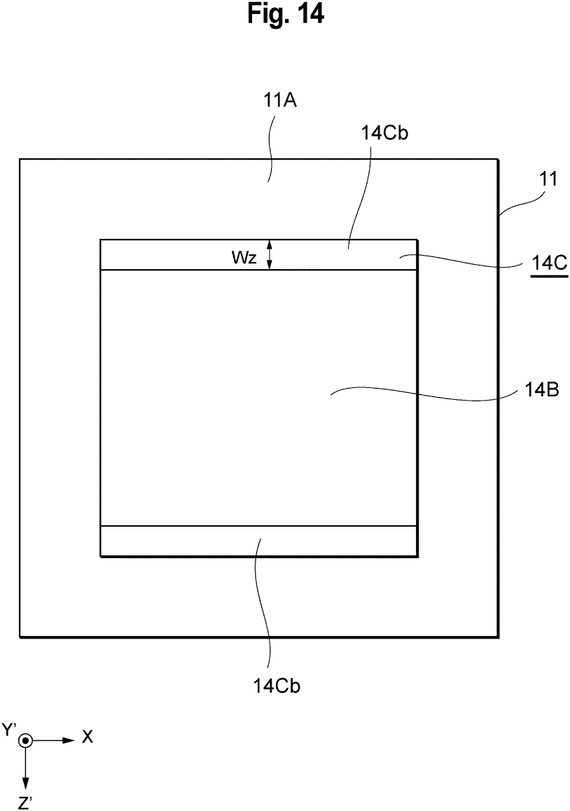

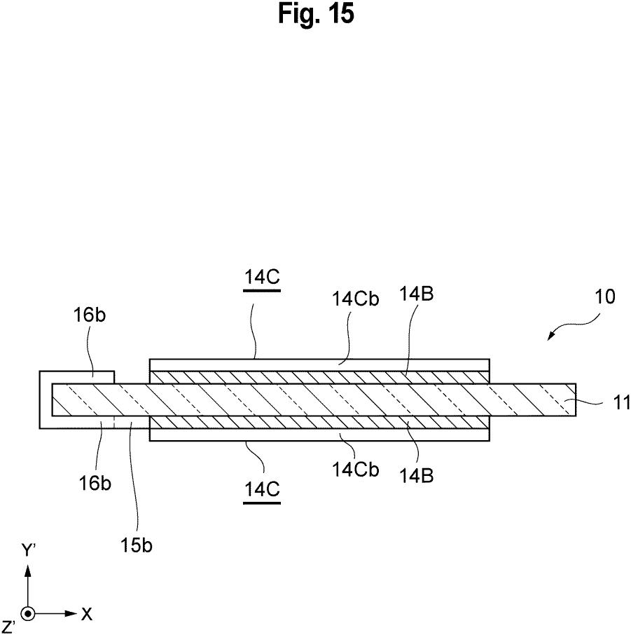

As shown in FIGS. 14 and 15, the first excitation electrode 14a has, for example, the flat plate portion 14B and the thick film portion 14C. The flat plate portion 14B has, for example, a rectangular shape and is provided on the first principal plane 11A of the crystal piece 11. Moreover, the thick film portion 14C protrudes from the upper surface of the flat plate portion 14B and includes, for example, second protruding portions 14Cb. The second protruding portions 14Cb are located at the ends in the Z′-axis direction on the second principal plane 11B of the crystal piece 11 and extend in the X-axis direction. The second protruding portions 14Cb are located, for example, at both ends in the Z′-axis direction on the second principal plane 11B of the crystal piece 11 and extend from one end to the other end in the X-axis direction on the second principal plane 11B of the crystal piece 11.

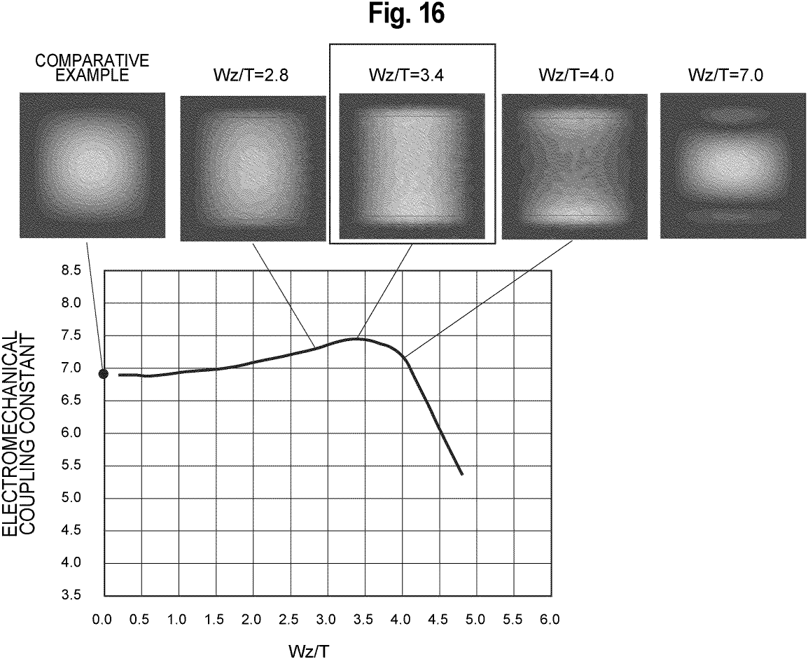

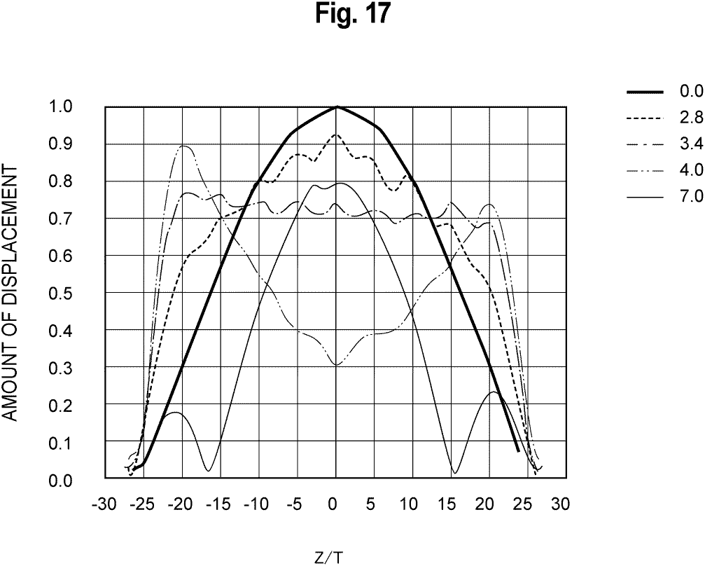

Next, the functions of the crystal oscillation element 10 according to the present embodiment will be described with reference to FIGS. 16 and 17. FIGS. 16 and 17 show vibration characteristics of the crystal oscillation element 10 predicted using a simulation model of the crystal oscillator 1 according to the present embodiment. In the simulation model of the crystal oscillator 1, aluminum is set as the material of the excitation electrode unit 14. Further, in the simulation model of the crystal oscillator 1, when a voltage is applied to the excitation electrode unit 14, the crystal piece 11 performs thickness-shear vibrations by vibrating in a plane defined by a thickness direction and the first base axis, the thickness direction being a direction intersecting the principal planes. FIG. 16 is a graph showing an electromechanical coupling constant of the crystal oscillation element 10 according to the present embodiment. FIG. 17 is a graph showing a vibration characteristic of the crystal oscillation element 10 according to the present embodiment. The vibration characteristic of the crystal oscillation element 10 indicates the vibration shape of the crystal oscillation element 10 during the thickness-shear vibration.

In the example shown in FIG. 16, the transition of a change in the electromechanical coupling constant of the crystal oscillation element 10 when the width Wz of the second protruding portion 14Cb is changed is shown. In the example shown in the same figure, the vertical axis represents the electromechanical coupling constant, and the horizontal axis represents the ratio of the width Wz of the second protruding portion 14Cb to the thickness T of the crystal piece 11. In this example, the value of the electromechanical coupling constant is “6.8” in a comparative example corresponding to the case where the crystal piece 11 is not provided with the second protruding portions 14Cb. Meanwhile, in the example corresponding to the case where the crystal piece 11 is provided with the second protruding portions 14Cb, in the case in which the ratio of the width Wz of the second protruding portion 14Cb to the thickness T of the crystal piece 11 is increased stepwise from “2.8” to “3.4”, “4.0”, and “7.0”, the maximum value of the electromechanical coupling constant is “7.4” when the ratio is “3.4”.

That is, when the excitation electrode unit 14 is provided with the second protruding portions 14Cb, the speed of sound propagating through the excitation electrode unit 14 partially decreases due to a mass load effect. Therefore, during the thickness-shear vibration of the crystal piece 11, the vibration wavelength of the second protruding portions 14Cb of the excitation electrode unit 14 is relatively shorter than the vibration wavelength of the flat plate portion 14B of the excitation electrode unit 14. The strain that occurs in the second protruding portions 14Cb of the excitation electrode unit 14 becomes relatively larger than the strain that occurs in the flat plate portion 14B of the excitation electrode unit 14. As a result, during the thickness-shear vibration of the crystal piece 11, strain is concentrated on the second protruding portions 14Cb of the excitation electrode unit 14, and the strain on the flat plate portion 14B of the excitation electrode unit 14 is relaxed and the amount of displacement becomes uniform, so that the electromechanical coupling constant of the crystal oscillation element 10 increases.

In the example shown in FIG. 17, a vibration characteristic of the crystal oscillation element 10 is shown with respect to the case where the ratio of the width Wz of the second protruding portion 14Cb to the thickness T of the crystal piece 11 is set so that the value of the electromechanical coupling constant becomes the maximum value of “7.4” in the example shown in FIG. 16. FIG. 15 is a diagram showing the amount of displacement for each position in the Z-axis direction in the crystal oscillation element 10. In the example shown in FIG. 17, a comparative example corresponding to the case where the second protruding portions 14Cb are not provided to the crystal piece 11, and an example corresponding to the case where the second protruding portions 14Cb are provided to the crystal piece 11 under the abovementioned conditions are shown in superposition with each other. As is also clear from the example shown in FIG. 17, the crystal oscillation element 10 of the example has a flat vibration shape during the thickness-shear vibration as compared with the crystal oscillation element 10 of the comparative example, and spurious oscillations, which are vibrations occurring at a frequency other than the main frequency, are advantageously reduced.

The crystal oscillation element 10 according to the present embodiment includes the crystal piece 11 having the first principal plane 11A and the second principal plane 11B, which are planes parallel to the plane specified by the X-axis and the Z′-axis, where the axes obtained by tilting the Y-axis and the Z-axis, among the X-axis, Y-axis, and Z-axis, which are the crystallographic axes, at a predetermined angle about the X-axis are taken as the Y′-axis and the Z′-axis, and the excitation electrode unit 14 provided at the first principal plane 11A and the second principal plane 11B of the crystal piece 11. In this aspect, when a voltage is applied to the excitation electrode unit 14, the crystal piece 11 performs thickness-shear vibrations by vibrating in a plane defined by a thickness direction and the first base axis, the thickness direction being a direction intersecting the principal planes, the excitation electrode unit 14 has the thick film portions 14C that are located at electrode ends in the directions along the first principal plane 11A and the second principal plane 11B of the crystal piece 11 and have a thickness larger than that of the flat plate portions 14B, the thick film portion 14C has second protruding portions 14Cb that are located at the ends in the axis direction of the Z′-axis on the second principal plane 11B of the crystal piece 11 and extend in the X-axis direction. In the crystal oscillation element 10, in the case where the second protruding portions 14Cb are provided, by contrast with the case where the second protruding portions 14Cb are not provided, during the thickness-shear vibration of the crystal piece 11, strain is concentrated on the second protruding portions 14Cb of the excitation electrode unit 14, and the strain on the flat plate portion 14B of the excitation electrode unit 14 is relaxed and the amount of displacement becomes uniform. Therefore, the value of the electromechanical coupling constant, which corresponds to the efficiency of the piezoelectric effect in the crystal oscillation element 10, increases, so that spurious oscillations, which are vibrations occurring at a frequency other than that of the main vibration, can be reduced.

### Fourth Exemplary Embodiment

In the fourth embodiment, descriptions of matters common to the first embodiment will be omitted, and only differences between the embodiments will be described. In particular, similar actions and effects resulting from similar configurations will not be mentioned sequentially for each embodiment.

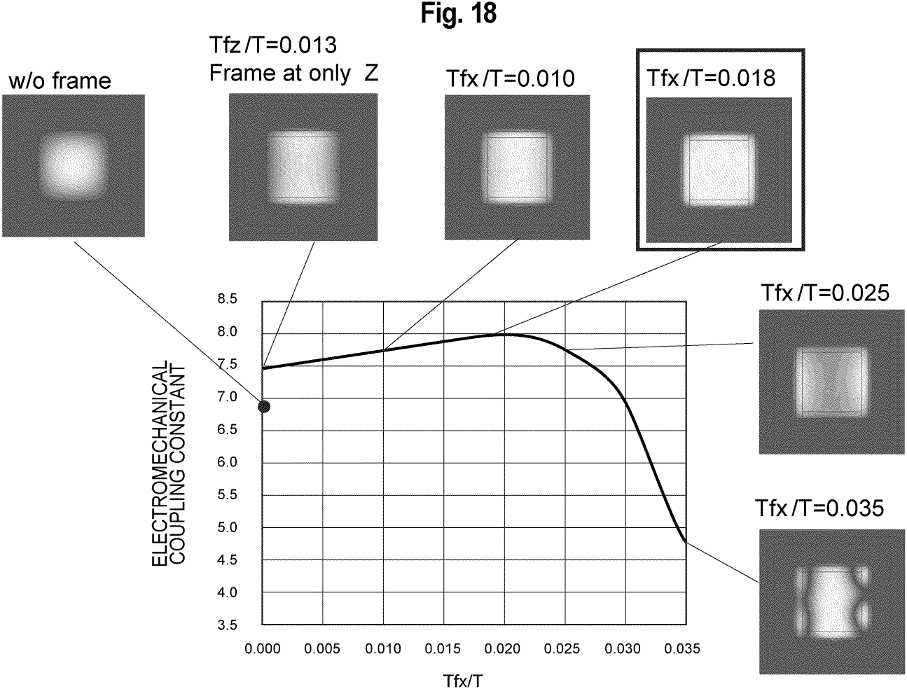

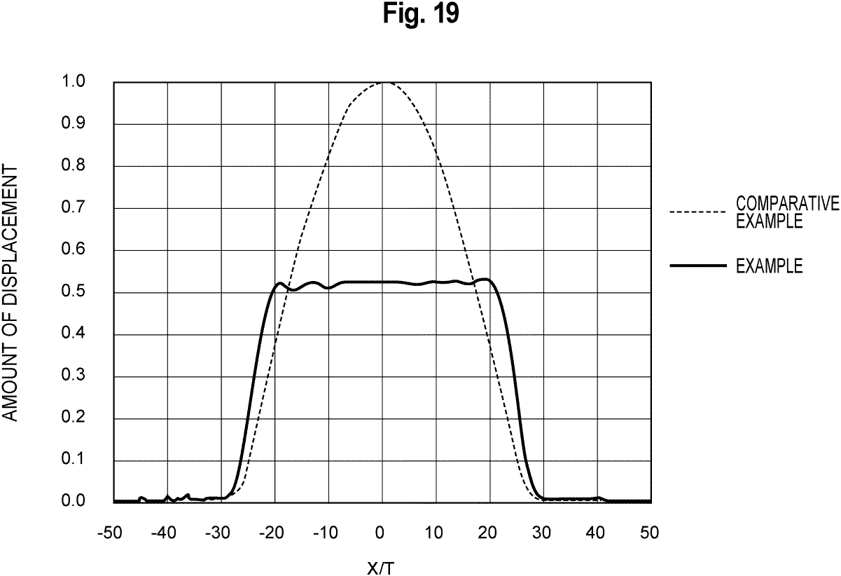

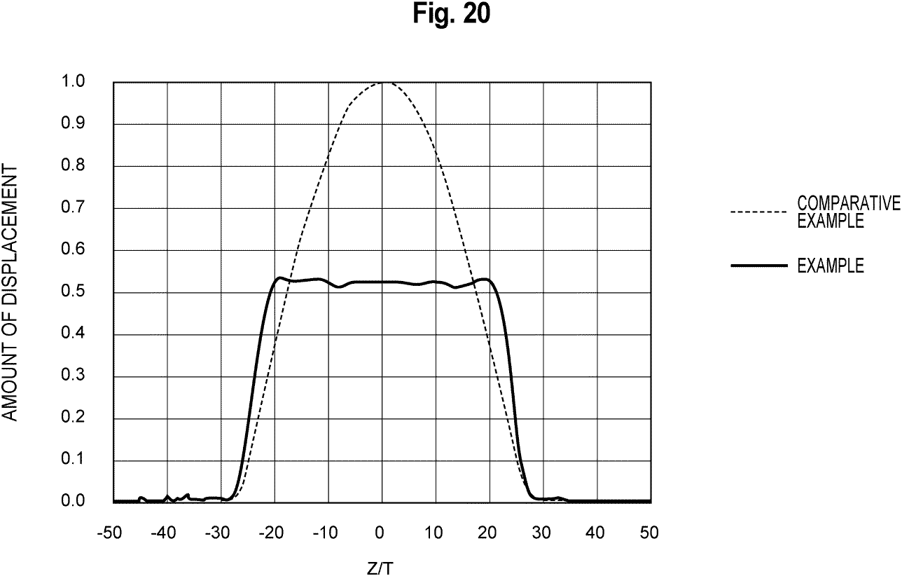

The functions of the crystal oscillator 1 according to the present embodiment will be described with reference to FIGS. 18 to 20. FIGS. 18 to 20 show vibration characteristics of the crystal oscillation element 10 predicted using a simulation model of the crystal oscillator 1 according to the present embodiment. In the simulation model of the crystal oscillator 1, aluminum is set as the material of the excitation electrode unit 14. Further, in the simulation model of the crystal oscillator 1, when a voltage is applied to the excitation electrode unit 14, the crystal piece 11 performs thickness-shear vibrations by vibrating in a plane defined by a thickness direction and the first base axis, the thickness direction being a direction intersecting the principal planes. FIG. 18 is a graph showing an electromechanical coupling constant of the crystal oscillation element 10 according to the present embodiment. The electromechanical coupling constant is a coefficient representing the conversion capability between electrical energy and mechanical energy, and the larger the value of this coefficient, the higher the conversion capability between electrical energy and mechanical energy. FIGS. 19 and 20 are graphs showing a vibration characteristic of the crystal oscillation element 10 according to the present embodiment. The vibration characteristic of the crystal oscillation element 10 indicates the vibration shape of the crystal oscillation element 10 during the thickness-shear vibration.

The example shown in FIG. 18 illustrates the transition of a change in the electromechanical coupling constant of the crystal oscillation element 10 when the width Wx of the first protruding portion 14Ca and the width Wz of the second protruding portion 14Cb are fixed to “4.5”, the ratio of the protrusion amount Tfz of the second protruding portion 14Cb to the thickness T of the crystal piece 11 is fixed to “0.013”, and the ratio of the protrusion amount Tfx of the first protruding portion 14Ca to the thickness T of the crystal piece 11 is changed. In the example shown in the same figure, the vertical axis represents the electromechanical coupling constant, and the horizontal axis represents the ratio of the protrusion amount Tfx of the first protruding portion 14Ca to the thickness T of the crystal piece 11. In this example, the value of the electromechanical coupling constant is “6.8” in a comparative example corresponding to the case where the excitation electrode unit 14 is not provided with the first protruding portions 14Ca and the second protruding portions 14Cb. Meanwhile, in the example corresponding to the case where the excitation electrode unit 14 is provided with the first protruding portions 14Ca and the second protruding portions 14Cb, in the case in which the ratio of the protrusion amount Tfx of the first protruding portion 14Ca to the thickness T of the crystal piece 11 is increased stepwise from “0.0” to “0.010”, “0.018”, “0.025”, and “0.035”, the value of the electromechanical coupling constant is “7.5” when the ratio is “0”, and the value of the electromechanical coupling constant tends to increase as the ratio increases. The maximum value of the electromechanical coupling constant is “8.0” when the ratio is “0.018”.

That is, when the excitation electrode unit 14 is provided with the first protruding portions 14Ca or the second protruding portions 14Cb, the speed of sound propagating through the excitation electrode unit 14 partially decreases due to a mass load effect. Therefore, during the thickness-shear vibration of the crystal piece 11, the vibration wavelength of the first protruding portions 14Ca or the second protruding portions 14Cb of the excitation electrode unit 14 is relatively shorter than the vibration wavelength of the flat plate portion 14B of the excitation electrode unit 14. The strain that occurs in the first protruding portions 14Ca or the second protruding portions 14Cb of the excitation electrode unit 14 becomes relatively larger than the strain that occurs in the flat plate portion 14B of the excitation electrode unit 14. As a result, during the thickness-shear vibration of the crystal piece 11, strain is concentrated on the first protruding portions 14Ca or the second protruding portions 14Cb of the excitation electrode unit 14, and the strain on the flat plate portion 14B of the excitation electrode unit 14 is relaxed and the amount of displacement becomes uniform, so that the electromechanical coupling constant of the crystal oscillation element 10 increases.

In the example shown in FIG. 18, the crystal oscillation element 10 satisfies the condition that the protrusion amount Tfx of the first protruding portion 14Ca is larger than the protrusion amount Tfz of the second protruding portion 14Cb under an assumption that the width Wx of the first protruding portion 14Ca is the same as the width Wz of the second protruding portion 14Cb. That is, since the crystal piece 11 is displaced in the X-axis direction during the thickness-shear vibration of the crystal piece 11, the strain generated in the excitation electrode unit 14 in the X-axis direction is larger than the strain in the Z′-axis direction. Therefore, the optimum value of the protrusion amount Tfx of the first protruding portion 14Ca for relaxing the strain in the X-axis direction is larger than the optimum value of the protrusion amount Tfz of the second protruding portion 14Cb for relaxing the strain in the Z′-axis direction.

In the example shown in FIGS. 19 and 20, a vibration characteristic of the crystal oscillation element 10 is shown with respect to the case where the ratio of the protrusion amount Tfx of the first protruding portion 14Ca to the thickness T of the crystal piece 11 is set so that the value of the electromechanical coupling constant becomes the maximum value of “8.0” in the example shown in FIG. 18. FIG. 19 is a diagram showing the amount of displacement for each position in the X-axis direction in the crystal oscillation element 10. FIG. 20 is a diagram showing the amount of displacement for each position in the Z-axis direction in the crystal oscillation element 10. In the example shown in FIGS. 19 and 20, a comparative example corresponding to the case where the first protruding portions 14Ca and the second protruding portions 14Cb are not provided in the crystal oscillation element 10, and an example corresponding to the case where the first protruding portions 14Ca and the second protruding portions 14Cb are provided to the crystal piece 11 under the abovementioned conditions are shown in superposition with each other. As is also clear from the example shown in FIGS. 19 and 20, the crystal oscillation element 10 of the example has a flat vibration shape during the thickness-shear vibration as compared with the crystal oscillation element 10 of the comparative example, and spurious oscillations, which are vibrations occurring at a frequency other than the main frequency, are advantageously reduced.

### Fifth Exemplary Embodiment

In the fifth embodiment, descriptions of matters common to the first embodiment will be omitted, and only differences between the embodiments will be described. In particular, similar actions and effects resulting from similar configurations will not be mentioned sequentially for each embodiment.

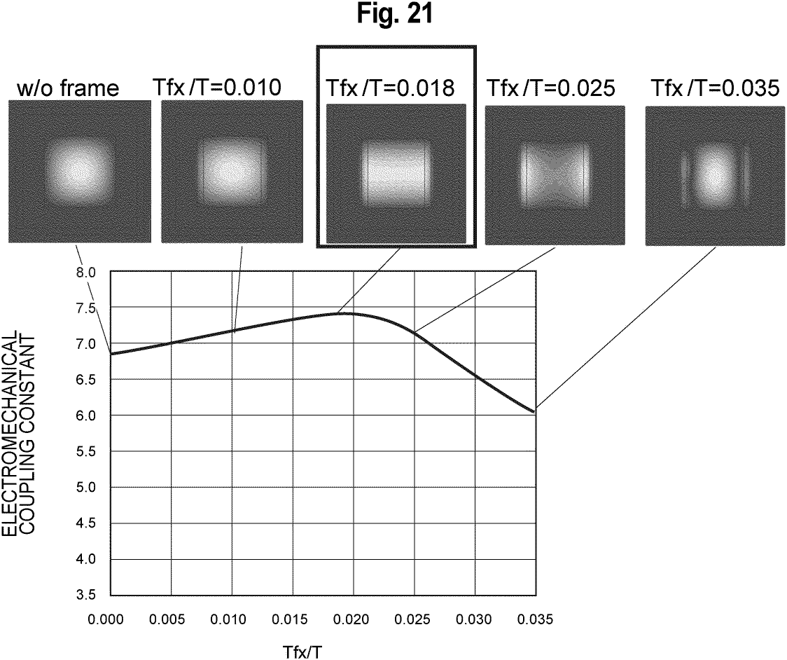

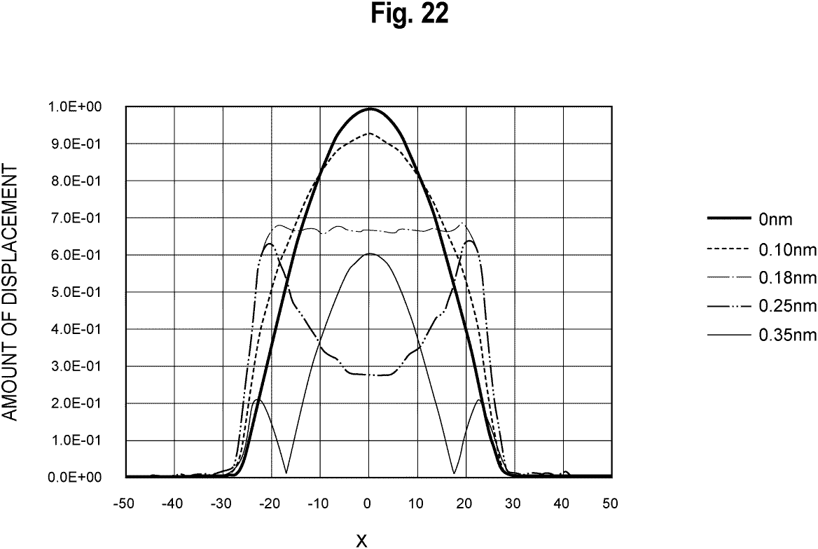

The functions of the crystal oscillator 1 according to the present embodiment will be described with reference to FIGS. 21 and 22. FIGS. 21 and 22 show vibration characteristics of the crystal oscillation element 10 predicted using a simulation model of the crystal oscillator 1 according to the present embodiment. In the simulation model of the crystal oscillator 1, aluminum is set as the material of the excitation electrode unit 14. Further, in the simulation model of the crystal oscillator 1, when a voltage is applied to the excitation electrode unit 14, the crystal piece 11 performs thickness-shear vibrations by vibrating in a plane defined by a thickness direction and the first base axis, the thickness direction being a direction intersecting the principal planes. FIG. 21 is a graph showing an electromechanical coupling constant of the crystal oscillation element 10 according to the present embodiment. FIG. 22 is a graph showing a vibration characteristic of the crystal oscillation element 10 according to the present embodiment. The vibration characteristic of the crystal oscillation element 10 indicates the vibration shape of the crystal oscillator 1 during the thickness-shear vibration.

In the example shown in FIG. 21, the transition of a change in the electromechanical coupling constant of the crystal oscillation element 10 when the ratio of the protrusion amount Tfx of the first protruding portion 14Ca to the thickness T of the crystal piece 11 is changed is shown. In the example shown in the same figure, the vertical axis represents the electromechanical coupling constant, and the horizontal axis represents the ratio of the protrusion amount Tfx of the first protruding portion 14Ca to the thickness T of the crystal piece 11. In this example, the value of the electromechanical coupling constant is “6.8” in a comparative example corresponding to the case where the crystal piece 11 is not provided with the first protruding portions 14Ca. Meanwhile, in the example corresponding to the case where the crystal piece 11 is provided with the first protruding portions 14Ca, in the case in which the ratio of the protrusion amount Tfx of the first protruding portion 14Ca to the thickness T of the crystal piece 11 is increased stepwise from “0.010” to “0.018”, “0.025”, and “0.035”, the maximum value of the electromechanical coupling constant is “7.5” when the ratio is “0.018”.

That is, when the excitation electrode unit 14 is provided with the first protruding portions 14Ca, the speed of sound propagating through the excitation electrode unit 14 partially decreases due to a mass load effect. Therefore, during the thickness-shear vibration of the crystal piece 11, the vibration wavelength of the first protruding portions 14Ca of the excitation electrode unit 14 is relatively shorter than the vibration wavelength of the flat plate portion 14B of the excitation electrode unit 14. The strain that occurs in the first protruding portions 14Ca of the excitation electrode unit 14 becomes relatively larger than the strain that occurs in the flat plate portion 14B of the excitation electrode unit 14. As a result, during the thickness-shear vibration of the crystal piece 11, strain is concentrated on the first protruding portions 14Ca of the excitation electrode unit 14, and the strain on the flat plate portion 14B of the excitation electrode unit 14 is relaxed and the amount of displacement becomes uniform, so that the electromechanical coupling constant of the crystal oscillation element 10 increases.

In the example shown in FIG. 22, a vibration characteristic of the crystal oscillation element 10 is shown with respect to the case where the ratio of the protrusion amount Tfx of the first protruding portion 14Ca to the thickness T of the crystal piece 11 is set so that the value of the electromechanical coupling constant becomes the maximum value of “7.5” in the example shown in FIG. 21. FIG. 22 is a diagram showing the amount of displacement for each position in the X-axis direction in the crystal oscillation element 10. In the example shown in FIG. 22, a comparative example corresponding to the case where the first protruding portions 14Ca are not provided to the crystal piece 11, and an example corresponding to the case where the first protruding portions 14Ca are provided to the crystal piece 11 under the abovementioned conditions are shown in superposition with each other. As is also clear from the example shown in FIG. 22, the crystal oscillation element 10 of the example has a flat vibration shape during the thickness-shear vibration as compared with the crystal oscillation element 10 of the comparative example, and spurious oscillations, which are vibrations occurring at a frequency other than the main frequency, are advantageously reduced.

### Sixth Exemplary Embodiment

In the sixth embodiment, descriptions of matters common to the first embodiment will be omitted, and only differences between the embodiments will be described. In particular, similar actions and effects resulting from similar configurations will not be mentioned sequentially for each embodiment.

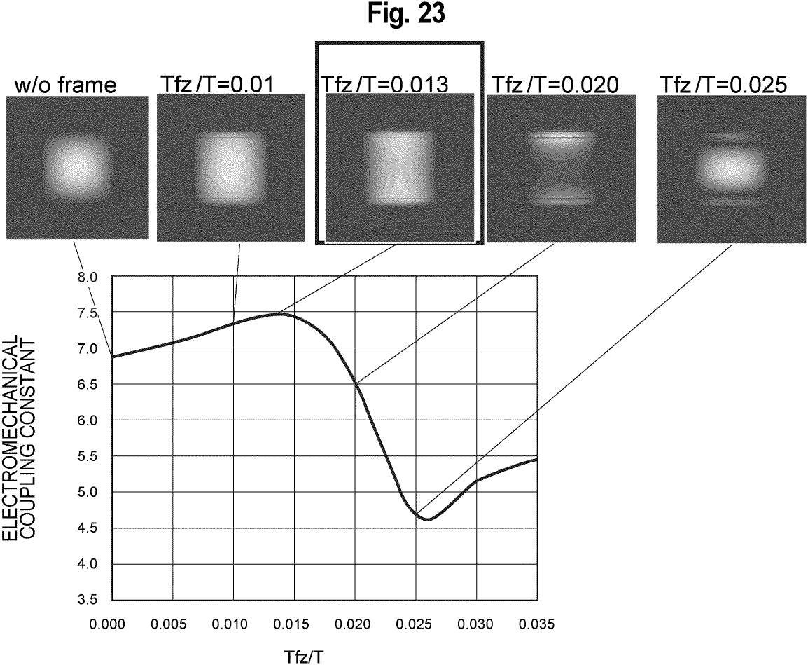

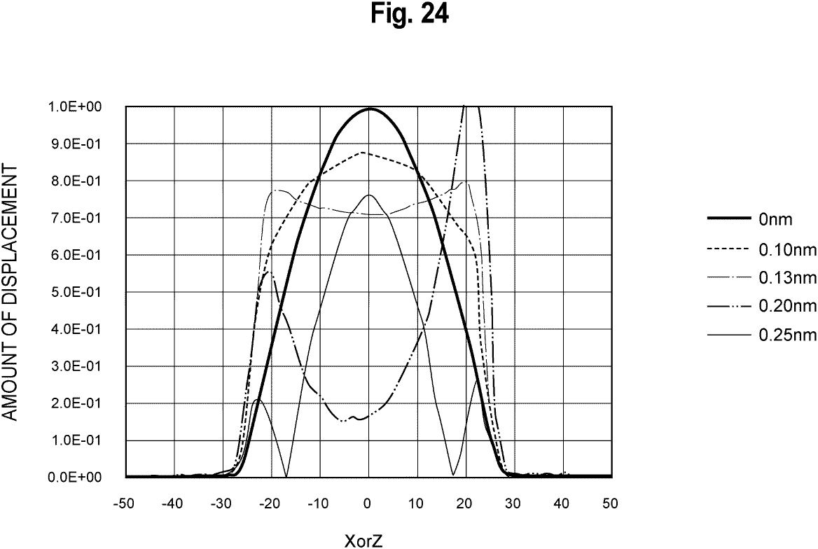

The functions of the crystal oscillation element 10 according to the present embodiment will be described with reference to FIGS. 23 and 24. FIGS. 23 and 24 show vibration characteristics of the crystal oscillation element 10 predicted using a simulation model of the crystal oscillator 1 according to the present embodiment. In the simulation model of the crystal oscillator 1, aluminum is set as the material of the excitation electrode unit 14. Further, in the simulation model of the crystal oscillator 1, when a voltage is applied to the excitation electrode unit 14, the crystal piece 11 performs thickness-shear vibrations by vibrating in a plane defined by a thickness direction and the first base axis, the thickness direction being a direction intersecting the principal planes. FIG. 23 is a graph showing an electromechanical coupling constant of the crystal oscillation element 10 according to the present embodiment. FIG. 24 is a graph showing a vibration characteristic of the crystal oscillation element 10 according to the present embodiment. The vibration characteristic of the crystal oscillation element 10 indicates the vibration shape of the crystal oscillation element 10 during the thickness-shear vibration.

In the example shown in FIG. 23, the transition of a change in the electromechanical coupling constant of the crystal oscillation element 10 when the ratio of the protrusion amount Tfz of the second protruding portion 14Cb to the thickness T of the crystal piece 11 is changed is shown. In the example shown in the same figure, the vertical axis represents the electromechanical coupling constant, and the horizontal axis represents the ratio of the protrusion amount Tfz of the second protruding portion 14Cb to the thickness T of the crystal piece 11. In this example, the value of the electromechanical coupling constant is “7.5” in a comparative example corresponding to the case where the crystal piece 11 is not provided with the second protruding portions 14Cb. Meanwhile, in the example corresponding to the case where the crystal piece 11 is provided with the second protruding portions 14Cb, in the case in which the ratio of the protrusion amount Tfz of the second protruding portion 14Cb to the thickness T of the crystal piece 11 is increased stepwise from “0.01” to “0.013”, “0.020”, and “0.025”, the maximum value of the electromechanical coupling constant is “7.5” when the ratio is “0.013”.

That is, when the excitation electrode unit 14 is provided with the second protruding portions 14Cb, the speed of sound propagating through the excitation electrode unit 14 partially decreases due to a mass load effect. Therefore, during the thickness-shear vibration of the crystal piece 11, the vibration wavelength of the second protruding portions 14Cb of the excitation electrode unit 14 is relatively shorter than the vibration wavelength of the flat plate portion 14B of the excitation electrode unit 14. The strain that occurs in the second protruding portions 14Cb of the excitation electrode unit 14 becomes relatively larger than the strain that occurs in the flat plate portion 14B of the excitation electrode unit 14. As a result, during the thickness-shear vibration of the crystal piece 11, strain is concentrated on the second protruding portions 14Cb of the excitation electrode unit 14, and the strain on the flat plate portion 14B of the excitation electrode unit 14 is relaxed and the amount of displacement becomes uniform, so that the electromechanical coupling constant of the crystal oscillation element 10 increases.

In the example shown in FIG. 24, a vibration characteristic of the crystal oscillation element 10 is shown with respect to the case where the ratio of the protrusion amount Tfz of the second protruding portion 14Cb to the thickness T of the crystal piece 11 is set so that the value of the electromechanical coupling constant becomes the maximum value of “7.5” in the example shown in FIG. 23. FIG. 24 is a diagram showing the amount of displacement for each position in the Z-axis direction in the crystal oscillation element 10. In the example shown in FIG. 24, a comparative example corresponding to the case where the second protruding portions 14Cb are not provided to the crystal piece 11, and an example corresponding to the case where the second protruding portions 14Cb are provided to the crystal piece 11 under the abovementioned conditions are shown in superposition with each other. As also shown in FIG. 24, the crystal oscillation element 10 of the example has a flat vibration shape during the thickness-shear vibration as compared with the crystal oscillation element 10 of the comparative example, and spurious oscillations, which are vibrations occurring at a frequency other than the main frequency, are advantageously reduced.

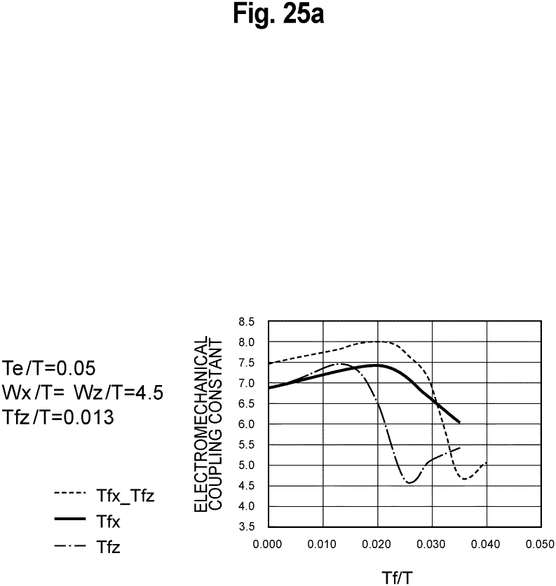

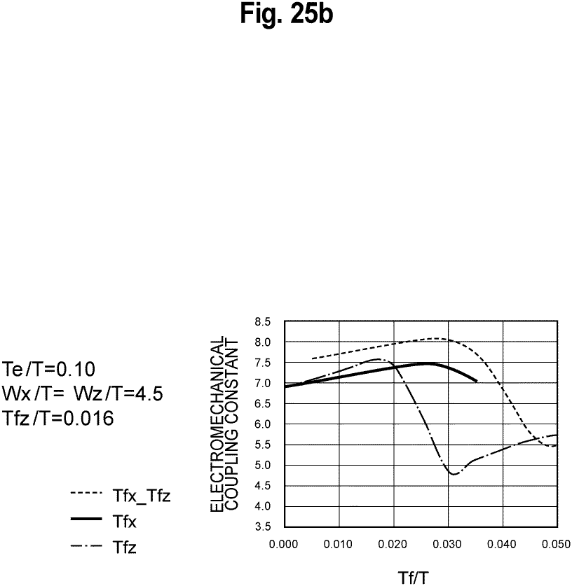

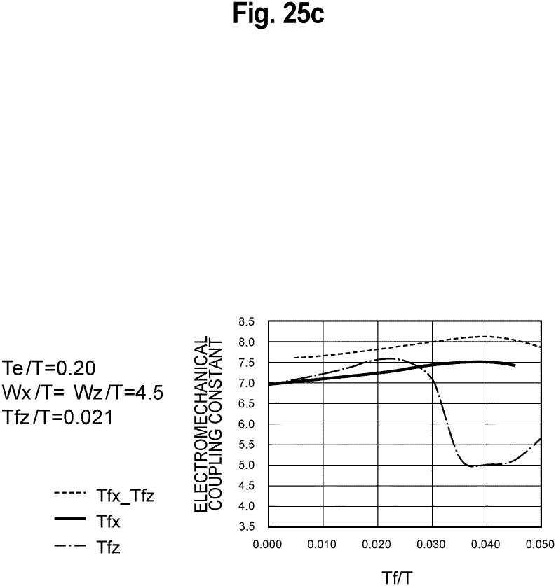

In the examples shown in FIGS. 25(a) to 25(c), cases are explained in which the thickness T of the crystal piece 11, the thickness Te of the flat plate portion 14B of the excitation electrode unit 14, and the thickness Tf of the thick film portion 14C of the excitation electrode unit 14 are changed as various parameters related to the crystal oscillation element 10. The thickness Tf corresponds to the protrusion amount of the thick film portion 14C from the flat plate portion 14B of the excitation electrode unit 14. FIG. 25(a) is a graph related to the case where the ratio of the thickness Te of the flat plate portion 14B of the excitation electrode unit 14 to the thickness T of the crystal piece 11 is “0.05” and the ratio of the protrusion amount Tfz of the second protruding portion 14Cb of the excitation electrode unit 14 to the thickness T of the crystal piece 11 is “0.013”. FIG. 25(b) is a graph related to the case where the ratio of the thickness Te of the flat plate portion 14B of the excitation electrode unit 14 to the thickness T of the crystal piece 11 is “0.10” and the ratio of the protrusion amount Tfz of the second protruding portion 14Cb of the excitation electrode unit 14 to the thickness T of the crystal piece 11 is “0.016”. FIG. 25(c) is a graph related to the case where the ratio of the thickness Te of the flat plate portion 14B of the excitation electrode unit 14 to the thickness T of the crystal piece 11 is “0.20” and the ratio of the protrusion amount Tfz of the second protruding portion 14Cb of the excitation electrode unit 14 to the thickness T of the crystal piece 11 is “0.021”. In any of these examples, in the case where the condition regarding the protrusion amount Tfx of the first protruding portion 14Ca that maximizes the electromechanical coupling constant is compared with the condition regarding the protrusion amount Tfz of the second protruding portion 14Cb that maximizes the electromechanical coupling constant, the protrusion amount Tfx of the first protruding portion 14Ca is larger than the protrusion amount Tfz of the second protruding portion 14Cb.

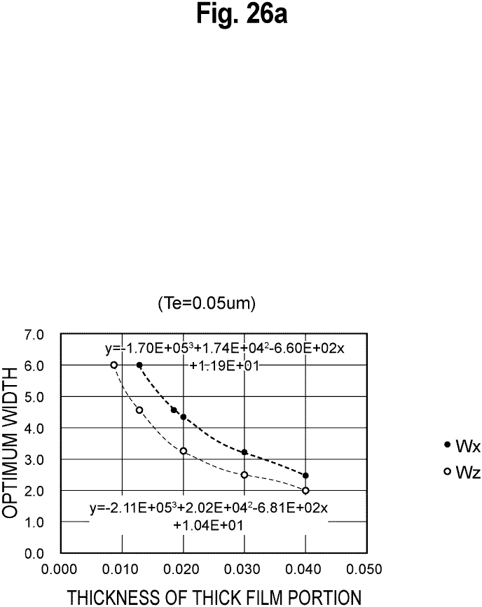

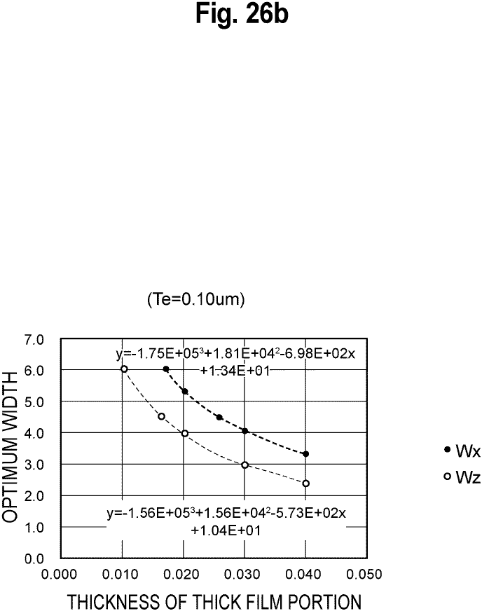

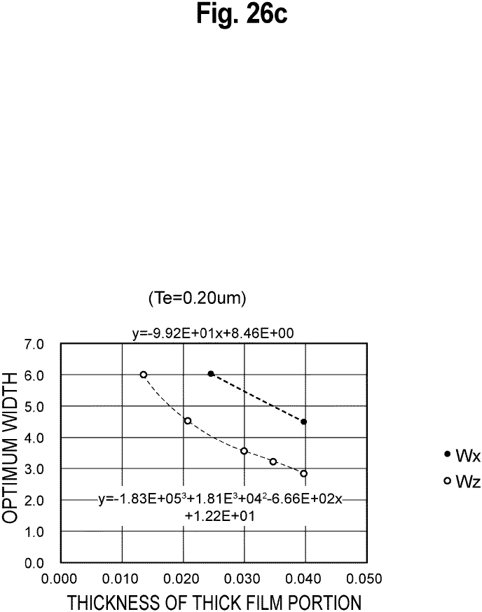

In the examples shown in FIGS. 26(a) to 26(c), cases are explained in which the thickness T of the crystal piece 11, the thickness Te of the flat plate portion 14B of the excitation electrode unit 14, and the thickness Tf of the thick film portion 14C of the excitation electrode unit 14 are changed as various parameters related to the crystal oscillation element 10. FIG. 26(a) is a graph related to the case where the thickness Te of the flat plate portion 14B of the excitation electrode unit 14 is “0.05 µm”. FIG. 26(b) is a graph related to the case where the thickness Te of the flat plate portion 14B of the excitation electrode unit 14 is “0.10 µm”. FIG. 26(c) is a graph related to the case where the thickness Te of the flat plate portion 14B of the excitation electrode unit 14 is “0.20 µm”. In any of these examples, in the case where the condition regarding the width Wx of the first protruding portion 14Ca that maximizes the electromechanical coupling constant is compared with the condition regarding the width Wz of the second protruding portion 14Cb that maximizes the electromechanical coupling constant, when the thickness Tf of the thick film portion 14C of the excitation electrode unit 14 is a common condition, the width Wx of the first protruding portion 14Ca is larger than the width Wz of the second protruding portion 14Cb. Further, as the thickness Tf of the thick film portion 14C of the excitation electrode unit 14 increases, the width Wx of the first protruding portion 14Ca and the width Wz of the second protruding portion 14Cb, which maximize the electromechanical coupling constant, decrease.

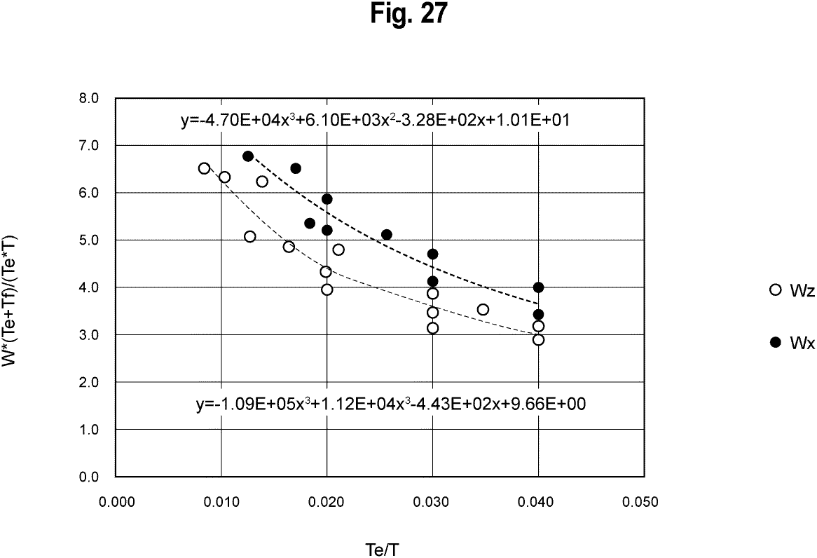

In the example shown in FIG. 27, cases are explained in which the thickness T of the crystal piece 11, the thickness Te of the flat plate portion 14B of the excitation electrode unit 14, and the thickness Tf of the thick film portion 14C of the excitation electrode unit 14 are changed as various parameters related to the crystal oscillation element 10. In the graph shown in FIG. 27, the vertical axis represents the ratio of the total value of the cross-sectional areas of the flat plate portion 14B and the thick film portion 14C of the excitation electrode unit 14 to the cross-sectional area of the flat plate portion 14B of the excitation electrode unit 14, and the horizontal axis represents the ratio of the thickness Te of the flat plate portion 14B of the excitation electrode unit 14 to the thickness T of the crystal piece 11. In this graph, in both the first protruding portion 14Ca and the second protruding portion 14Cb, the total value of the cross-sectional areas of the flat plate portion 14B and the thick film portion 14C of the excitation electrode unit 14 to the cross-sectional area of the flat plate portion 14B of the excitation electrode unit 14 decreases as the ratio of the thickness Tf of the thick film portion 14C of the excitation electrode unit 14 to the thickness T of the crystal piece 11 increases.

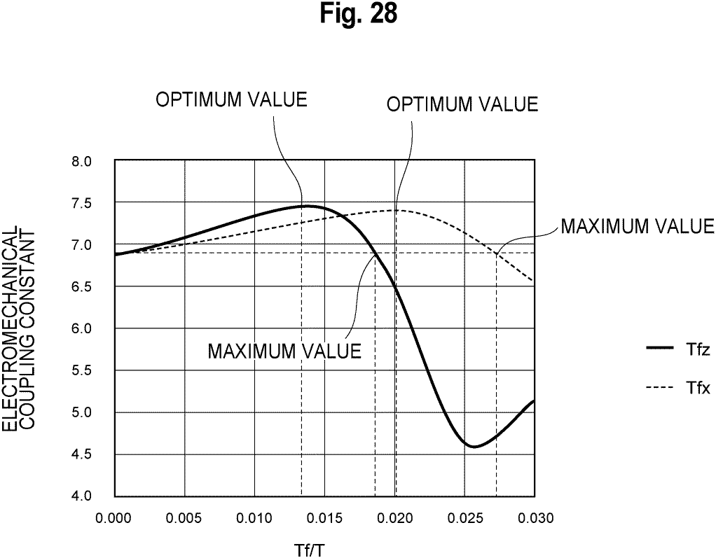

The example shown in FIG. 28 illustrates the transition of a change in the electromechanical coupling constant of the crystal oscillation element 10 when the width Wx of the first protruding portion 14Ca or the width Wz of the second protruding portion 14Cb is fixed, and the ratio of the protrusion amount Tfx of the first protruding portion 14Ca or the ratio of the protrusion amount Tfz of the second protruding portion 14Cb to the thickness T of the crystal piece 11 is changed. In the example shown in the same figure, the vertical axis represents the electromechanical coupling constant, and the horizontal axis represents the ratio of the protrusion amount Tfx of the first protruding portion 14Ca to the thickness T of the crystal piece 11. In this example, the value of the electromechanical coupling constant is “6.8” at the point where (Tf/T = 0) which corresponds to the case where the excitation electrode unit 14 is not provided with the first protruding portions 14Ca or the second protruding portions 14Cb. Meanwhile, where the excitation electrode unit 14 is provided with the first protruding portions 14Ca, the electromechanical coupling constant assumes a maximum value of “7.5” at the point where (Tf/T = 0.013). In this example, the point where (Tf/T = 0.013) corresponds to the optimum value of the ratio of the protrusion amount Tfx of the first protruding portion 14Ca to the thickness T of the crystal piece 11. Further, when the excitation electrode unit 14 is provided with the first protruding portions 14Ca, the value of the electromechanical coupling constant at the point where (Tf/T = 0.018) matches “6.8” which corresponds to the case where the excitation electrode unit 14 is not provided with the first protruding portions 14Ca or the second protruding portions 14Cb. In this example, the point where (Tf/T = 0.018) corresponds to the maximum value of the ratio of the protrusion amount Tfx of the first protruding portion 14Ca to the thickness T of the crystal piece 11. Further, when the excitation electrode unit 14 is provided with the second protruding portions 14Cb, the value of the electromechanical coupling constant becomes the maximum value “7.3” at the point where (Tf/T = 0.020). In this example, the point where (Tf/T = 0.020) corresponds to the optimum value of the ratio of the protrusion amount Tfz of the second protruding portion 14Cb to the thickness T of the crystal piece 11. Further, when the excitation electrode unit 14 is provided with the second protruding portions 14Cb, the value of the electromechanical coupling constant at the point where (Tf/T = 0.028) matches “6.8” which corresponds to the case where the excitation electrode unit 14 is not provided with the first protruding portions 14Ca or the second protruding portions 14Cb. In this example, the point where (Tf/T = 0.028) corresponds to the maximum value of the ratio of the protrusion amount Tfz of the second protruding portion 14Cb to the thickness T of the crystal piece 11 at which the vibration characteristic of the crystal oscillation element 10 satisfies the predetermined condition. The predetermined condition is, for example, that the electromechanical coupling constant of the crystal oscillation element 10 is equal to or greater than that in the case where the crystal oscillator 1 is not provided with the first protruding portions 14Ca and the second protruding portions 14Cb, and is satisfied when the effect of increasing the electromechanical coupling constant is obtained.

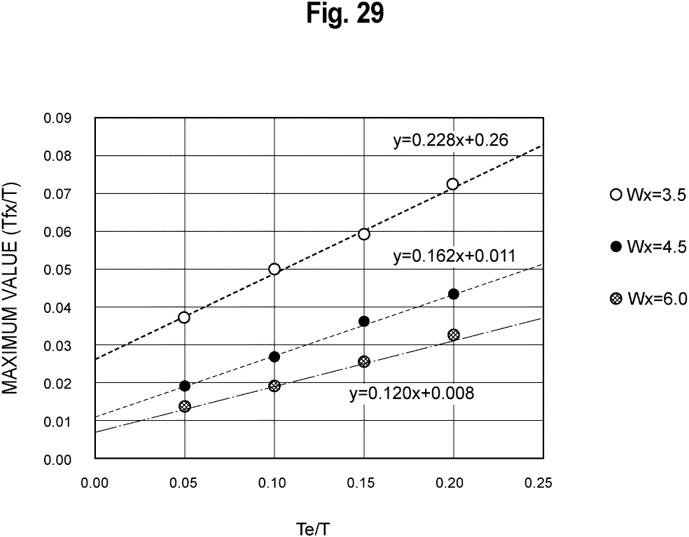

The example shown in FIG. 29 illustrates the transition of a change in the maximum value of Tfx/T at which the effect of increasing the electromechanical coupling constant when changing the ratio of the thickness Te of the flat plate portion 14B of the excitation electrode unit 14 to the thickness T of the crystal piece 11 cannot be obtained. In this example, a graph is shown for the cases where the width Wx of the first protruding portion 14Ca of the excitation electrode unit 14 is “3.5 (µm)”, “4.5 (µm)”, and “6.0 (µm)”. In this graph, in any of the cases, the maximum value of Tfx/T at which the effect of increasing the electromechanical coupling constant cannot be obtained increases as the ratio of the thickness Te of the flat plate portion 14B of the excitation electrode unit 14 to the thickness T of the crystal piece 11 increases. Further, the maximum value of Tfx/T at which the effect of increasing the electromechanical coupling constant cannot be obtained is expressed by the linear function “A x (Te/T) + B” when the ratio of the thickness Te of the flat plate portion 14B of the excitation electrode unit 14 to the thickness T of the crystal piece 11 is taken as a variable.

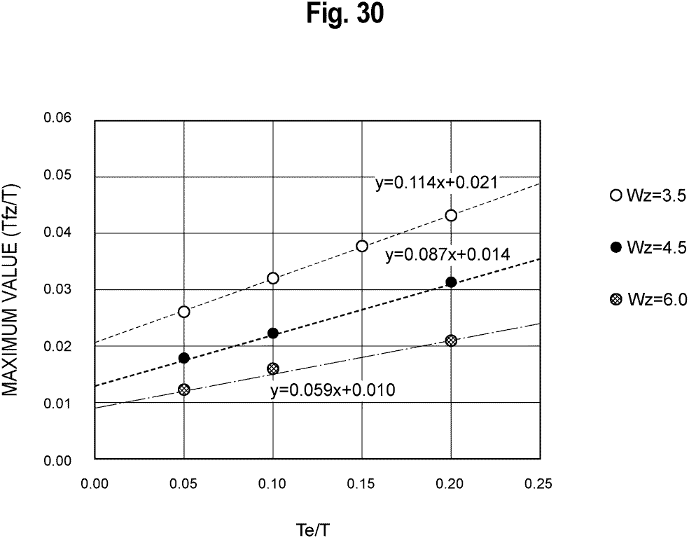

The example shown in FIG. 30 illustrates the transition of a change in the maximum value of Tfz/T at which the effect of increasing the electromechanical coupling constant when changing the ratio of the thickness Te of the flat plate portion 14B of the excitation electrode unit 14 to the thickness T of the crystal piece 11 cannot be obtained. In this example, a graph is shown for the cases where the width Wz of the second protruding portion 14Cb of the excitation electrode unit 14 is “3.5 (µm)”, “4.5 (µm)”, and “6.0 (µm)”. In this graph, in any of the cases, the maximum value of Tfz/T at which the effect of increasing the electromechanical coupling constant cannot be obtained increases as the ratio of the thickness Te of the flat plate portion 14B of the excitation electrode unit 14 to the thickness T of the crystal piece 11 increases. Further, the maximum value of Tfz/T at which the effect of increasing the electromechanical coupling constant cannot be obtained is expressed by the linear function “A x (Te/T) + B” when the ratio of the thickness Te of the flat plate portion 14B of the excitation electrode unit 14 to the thickness T of the crystal piece 11 is taken as a variable.

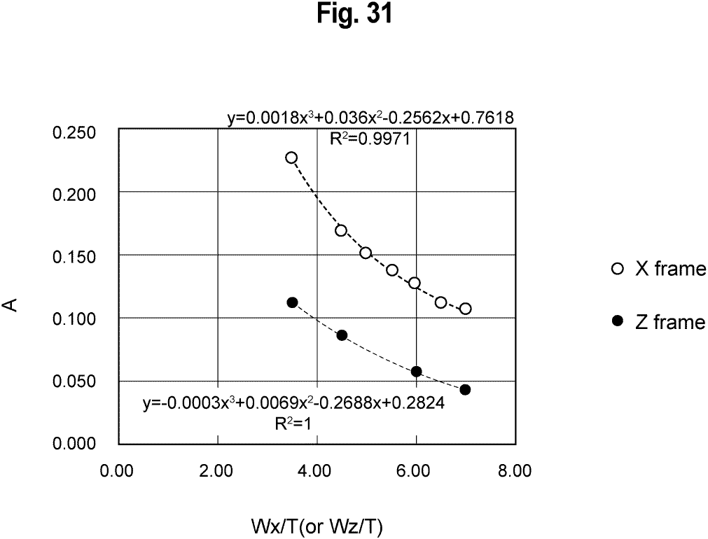

The example shown in FIG. 31 illustrates the transition of a change in the coefficient A of the abovementioned linear function when changing the ratio of the width Wx of the first protruding portion 14Ca or the ratio of the width Wz of the second protruding portion 14Cb of the excitation electrode unit 14 to the thickness T of the crystal piece 11. In this example, in any of the cases, the coefficient A of the linear function becomes smaller as the ratio of the width Wx of the first protruding portion 14Ca or the ratio of the width Wz of the second protruding portion 14Cb of the excitation electrode unit 14 to the thickness T of the crystal piece 11 increases.

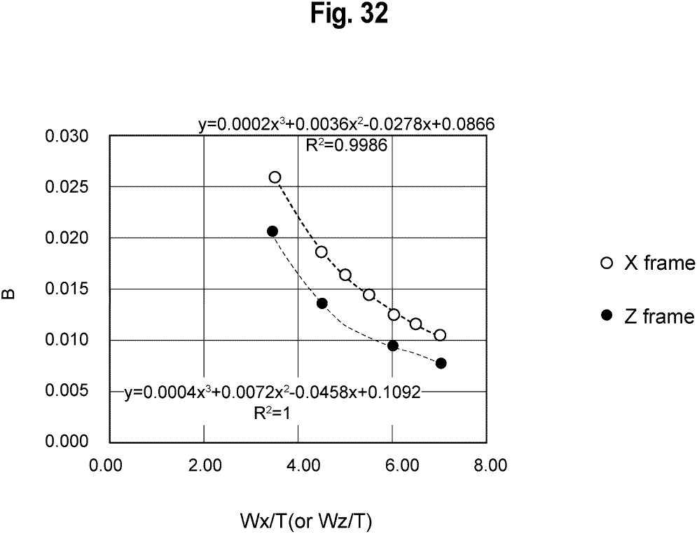

The example shown in FIG. 32 illustrates the transition of a change in the coefficient B of the abovementioned linear function when changing the ratio of the width Wx of the first protruding portion 14Ca or the ratio of the width Wz of the second protruding portion 14Cb of the excitation electrode unit 14 to the thickness T of the crystal piece 11. In this example, in any of the cases, the coefficient B of the linear function becomes smaller as the ratio of the width Wx of the first protruding portion 14Ca or the ratio of the width Wz of the second protruding portion 14Cb of the excitation electrode unit 14 to the thickness T of the crystal piece 11 increases.

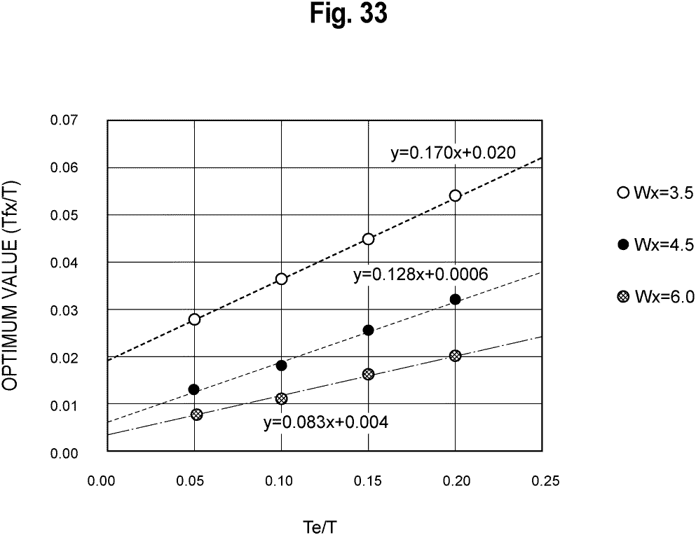

The example shown in FIG. 33 illustrates the transition of a change in the optimum value of Tfx/T that maximizes the electromechanical coupling constant when changing the ratio of the thickness Te of the flat plate portion 14B of the excitation electrode unit 14 to the thickness T of the crystal piece 11. In this example, a graph is shown for the cases where the width Wx of the first protruding portion 14Ca of the excitation electrode unit 14 is “3.5 (µm)”, “4.5 (µm)”, and “6.0 (µm)”.In this graph, in any of the cases, the optimum value of Tfx/T that maximizes the electromechanical coupling constant increases as the ratio of the thickness Te of the flat plate portion 14B of the excitation electrode unit 14 to the thickness T of the crystal piece 11 increases. Further, the optimum value of Tfx/T that maximizes the electromechanical coupling constant is expressed by the linear function “A x (Te/T) + B” when the ratio of the thickness Te of the flat plate portion 14B of the excitation electrode unit 14 to the thickness T of the crystal piece 11 is taken as a variable.

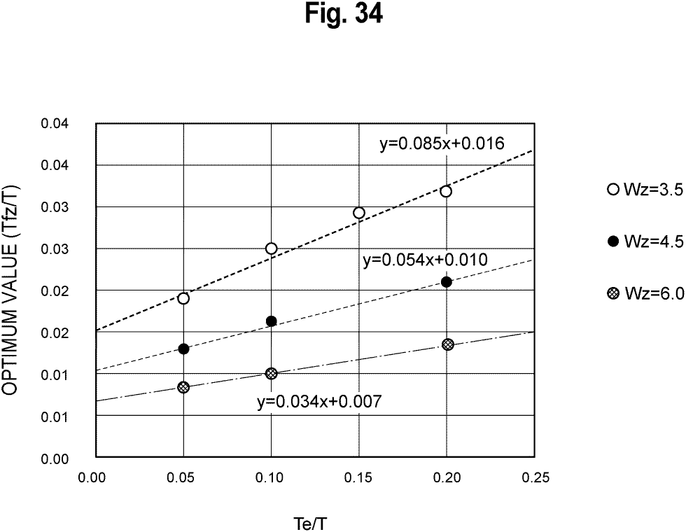

The example shown in FIG. 34 illustrates the transition of a change in the optimum value of Tfz/T that maximizes the electromechanical coupling constant when changing the ratio of the thickness Te of the flat plate portion 14B of the excitation electrode unit 14 to the thickness T of the crystal piece 11. In this example, a graph is shown for the cases where the width Wz of the second protruding portion 14Cb of the excitation electrode unit 14 is “3.5 (µm)”, “4.5 (µm)”, and “6.0 (µm)”.In this graph, in any of the cases, the optimum value of Tfz/T that maximizes the electromechanical coupling constant increases as the ratio of the thickness Te of the flat plate portion 14B of the excitation electrode unit 14 to the thickness T of the crystal piece 11 increases. Further, the optimum value of Tfz/T that maximizes the electromechanical coupling constant is expressed by the linear function “A x (Te/T) + B” when the ratio of the thickness Te of the flat plate portion 14B of the excitation electrode unit 14 to the thickness T of the crystal piece 11 is taken as a variable.

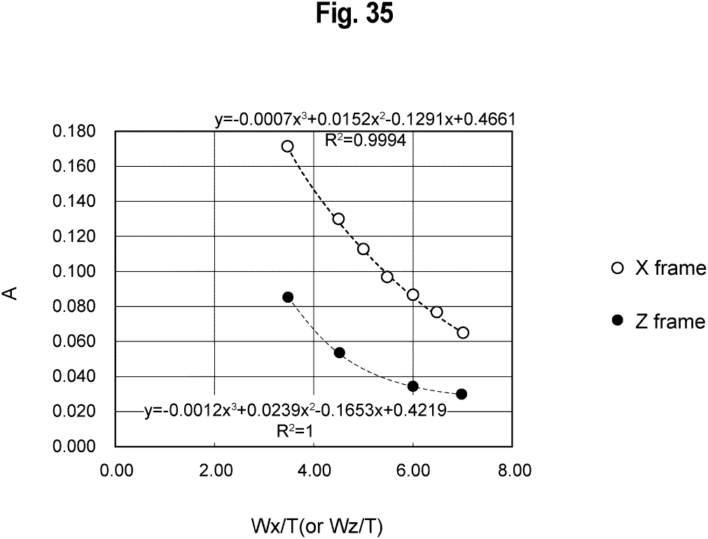

The example shown in FIG. 35 illustrates the transition of a change in the coefficient A of the abovementioned linear function when changing the ratio of the width Wx of the first protruding portion 14Ca or the ratio of the width Wz of the second protruding portion 14Cb of the excitation electrode unit 14 to the thickness T of the crystal piece 11. In this example, in any of the cases, the coefficient A of the linear function becomes smaller as the ratio of the width Wx of the first protruding portion 14Ca or the ratio of the width Wz of the second protruding portion 14Cb of the excitation electrode unit 14 to the thickness T of the crystal piece 11 increases.

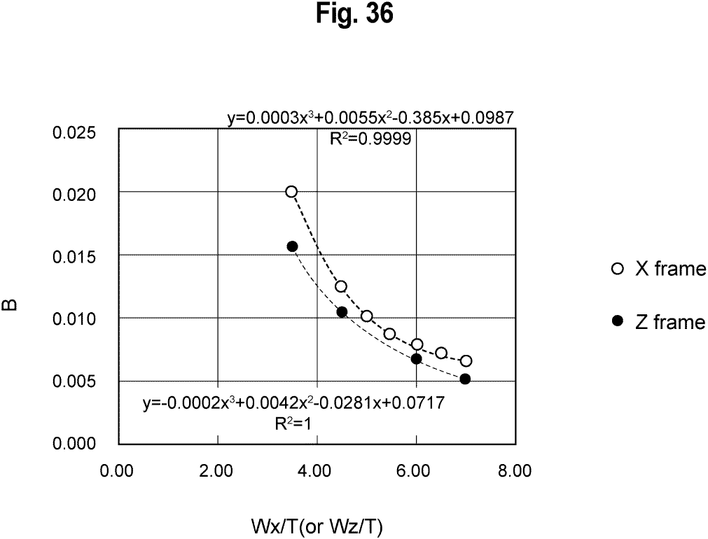

The example shown in FIG. 36 illustrates the transition of a change in the coefficient B of the abovementioned linear function when changing the ratio of the width Wx of the first protruding portion 14Ca or the ratio of the width Wz of the second protruding portion 14Cb of the excitation electrode unit 14 to the thickness T of the crystal piece 11. In this example, in any of the cases, the coefficient B of the linear function becomes smaller as the ratio of the width Wx of the first protruding portion 14Ca or the ratio of the width Wz of the second protruding portion 14Cb of the excitation electrode unit 14 to the thickness T of the crystal piece 11 increases.

### Seventh Exemplary Embodiment

In the seventh embodiment, descriptions of matters common to the first embodiment will be omitted, and only differences between the embodiments will be described. In particular, similar actions and effects resulting from similar configurations will not be mentioned sequentially for each embodiment.

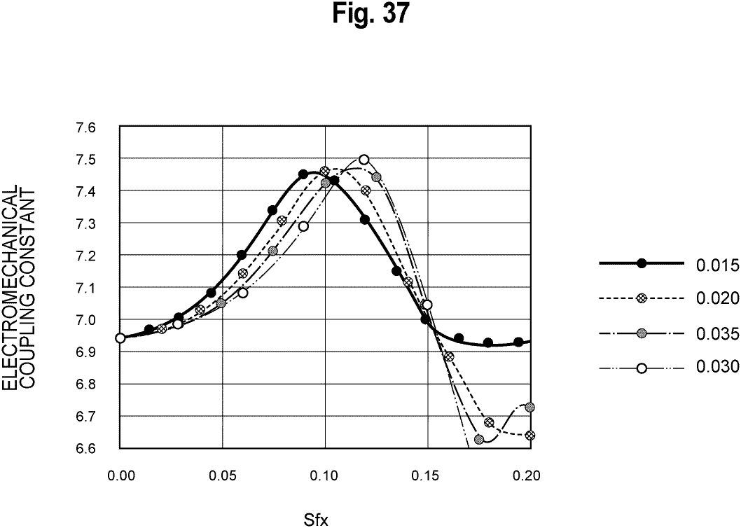

The example shown in FIG. 37 illustrates the transition in a change of the electromechanical coupling constant when changing the cross-sectional area of the first protruding portion 14Ca cut along the protrusion direction of the first protruding portion 14Ca. In this example, a graph is shown for the cases where the ratio of the thickness Tf of the flat plate portion 14B of the excitation electrode unit 14 to the thickness T of the crystal piece 11 is “0.015”, “0.020”, “0.025”, and “0.030”. In this graph, in any of the cases, the maximum value of the cross-sectional area of the first protruding portion at which the effect of increasing the electromechanical coupling constant cannot be obtained is a substantially constant value.

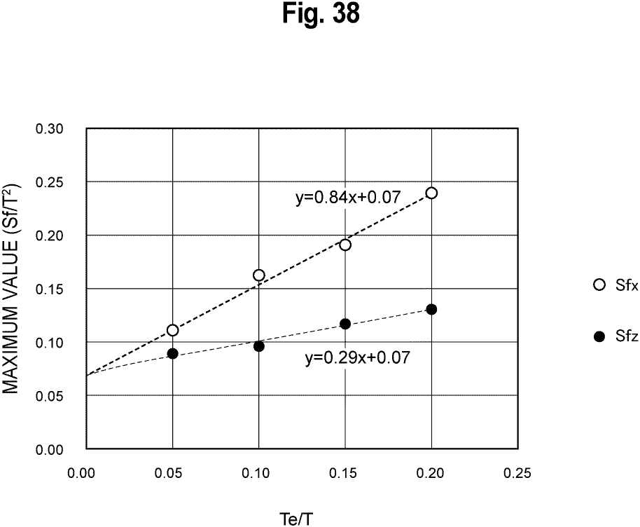

The example shown in FIG. 38 illustrates the transition in a change of the maximum value of the cross-sectional area of the first protruding portion and the second protruding portion at which the effect of increasing the electromechanical coupling constant cannot be obtained when changing the ratio of the cross-sectional area Sfx of the first protruding portion 14Ca (e.g., a cross-sectional area of the first protruding portion 14Ca cut in the direction along the plane defined by the first base axis and the thickness direction of the crystal piece 11) or the ratio of the cross-sectional area Sfz of the second protruding portion 14Cb (e.g., a cross-sectional area of the second protruding portion 14Cb cut in the direction along the plane defined by the second base axis and the thickness direction of the crystal piece 11) of the excitation electrode unit 14 to the thickness T of the crystal piece 11. In this example, in any of the cases, the maximum value of the cross-sectional area of the first protruding portion and the second protruding portion at which the effect of increasing the electromechanical coupling constant cannot be obtained increases as the ratio of the thickness Te of the flat plate portion 14B of the excitation electrode unit 14 to the thickness T of the crystal piece 11 increases. Further, the maximum value of the cross-sectional area of the first protruding portion and the second protruding portion at which the effect of increasing the electromechanical coupling constant cannot be obtained is expressed by the linear function “A x (Te/T) + B” when the ratio of the thickness Te of the flat plate portion 14B of the excitation electrode unit 14 to the thickness T of the crystal piece 11 is taken as a variable.

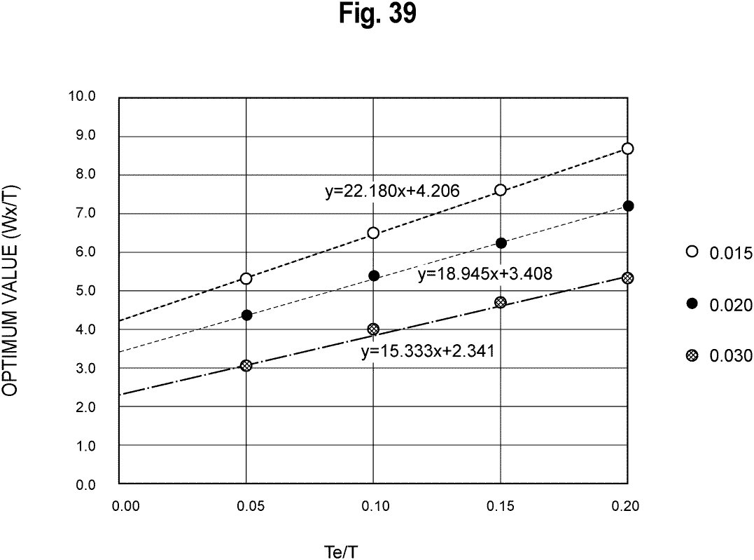

The example shown in FIG. 39 illustrates the transition in a change of the optimum value of Wx/T that maximizes the electromechanical coupling constant when changing the ratio of the thickness Te of the flat plate portion 14B of the excitation electrode unit 14 to the thickness T of the crystal piece 11. In this example, a graph is shown for the cases where the ratio of the protrusion amount Tfx of the first protruding portion 14Ca of the excitation electrode unit 14 to the thickness T of the crystal piece 11 is “0.015”, “0.020”, and “0.030”. In this graph, in any of the cases, the optimum value of Wx/T that maximizes the electromechanical coupling constant increases as the ratio of the thickness Te of the flat plate portion 14B of the excitation electrode unit 14 to the thickness T of the crystal piece 11 increases. Further, the optimum value of Wx/T that maximizes the electromechanical coupling constant is expressed by the linear function “A x (Te/T) + B” when the ratio of the thickness Te of the flat plate portion 14B of the excitation electrode unit 14 to the thickness T of the crystal piece 11 is taken as a variable.

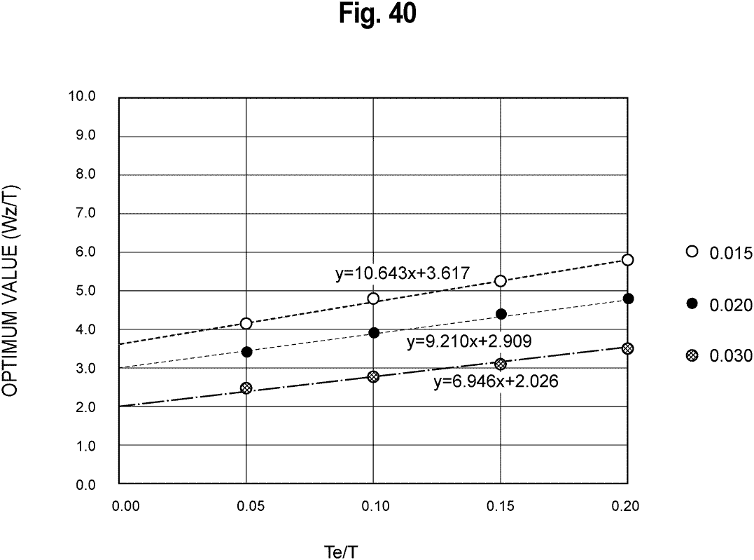

The example shown in FIG. 40 illustrates the transition in a change of the optimum value of Wz/T that maximizes the electromechanical coupling constant when changing the ratio of the thickness Te of the flat plate portion 14B of the excitation electrode unit 14 to the thickness T of the crystal piece 11. In this example, a graph is shown for the cases where the ratio of the protrusion amount Tfz of the second protruding portion 14Cb of the excitation electrode unit 14 to the thickness T of the crystal piece 11 is “0.015”, “0.020”, and “0.030”. In this graph, in any of the cases, the optimum value of Wz/T that maximizes the electromechanical coupling constant increases as the ratio of the thickness Te of the flat plate portion 14B of the excitation electrode unit 14 to the thickness T of the crystal piece 11 increases. Further, the optimum value of Wz/T that maximizes the electromechanical coupling constant is expressed by the linear function “A x (Te/T) + B” when the ratio of the thickness Te of the flat plate portion 14B of the excitation electrode unit 14 to the thickness T of the crystal piece 11 is taken as a variable.

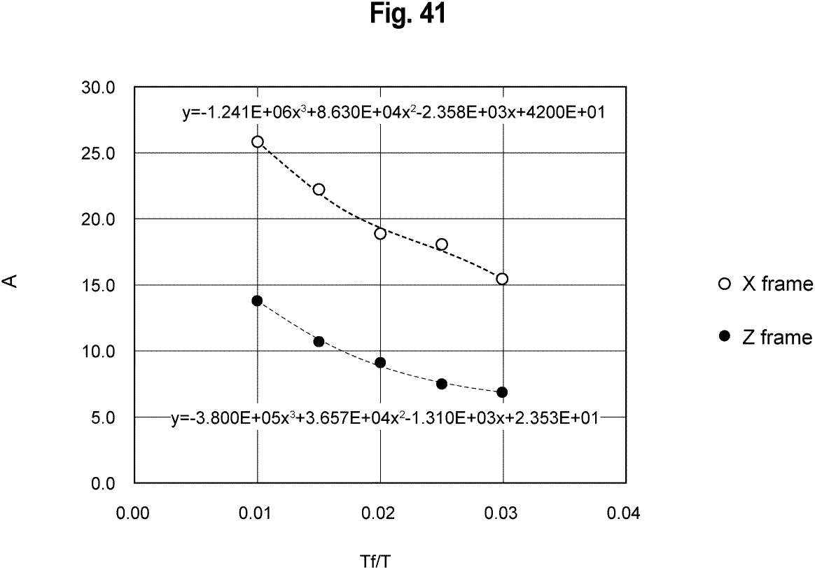

The example shown in FIG. 41 illustrates the transition of a change in the coefficient A of the abovementioned linear function when changing the ratio of the protrusion amount Tfx of the first protruding portion 14Ca or the ratio of the protrusion amount Tfz of the second protruding portion 14Cb of the excitation electrode unit 14 to the thickness T of the crystal piece 11. In this example, in any of the cases, the coefficient A of the linear function becomes smaller as the ratio of the protrusion amount Tfx of the first protruding portion 14Ca or the ratio of the protrusion amount Tfz of the second protruding portion 14Cb of the excitation electrode unit 14 to the thickness T of the crystal piece 11 increases.

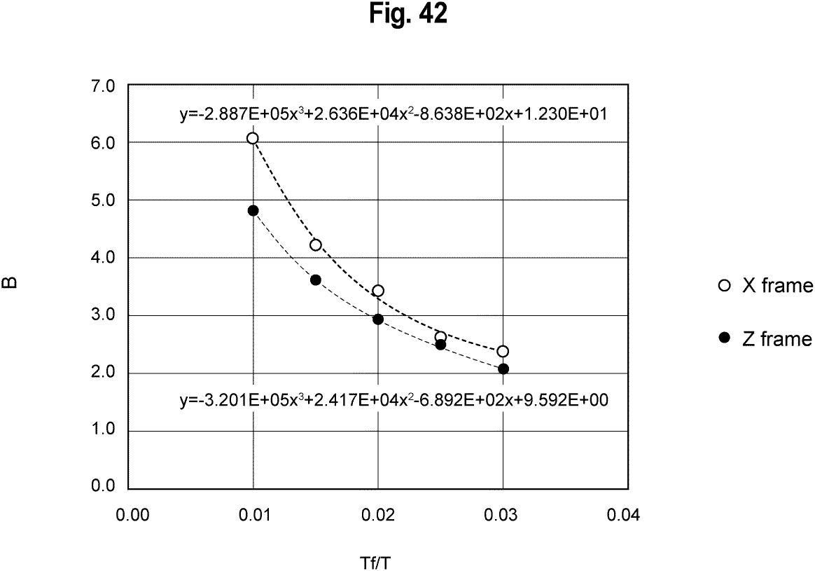

The example shown in FIG. 42 illustrates the transition of a change in the coefficient B of the abovementioned linear function when changing the ratio of the protrusion amount Tfx of the first protruding portion 14Ca or the ratio of the protrusion amount Tfz of the second protruding portion 14Cb of the excitation electrode unit 14 to the thickness T of the crystal piece 11. In this example, in any of the cases, the coefficient B of the linear function becomes smaller as the ratio of the protrusion amount Tfx of the first protruding portion 14Ca or the ratio of the protrusion amount Tfz of the second protruding portion 14Cb of the excitation electrode unit 14 to the thickness T of the crystal piece 11 increases.

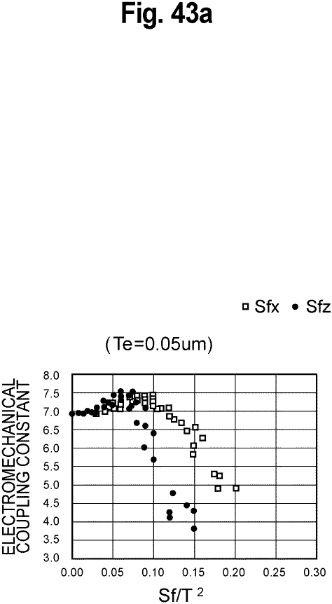

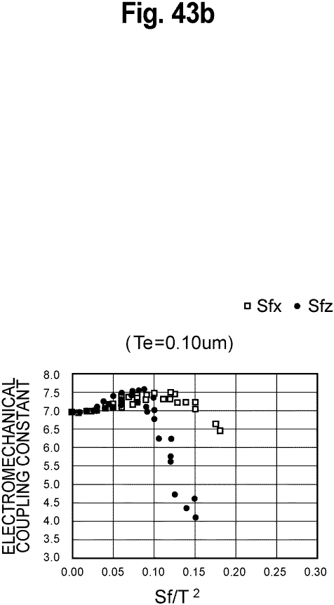

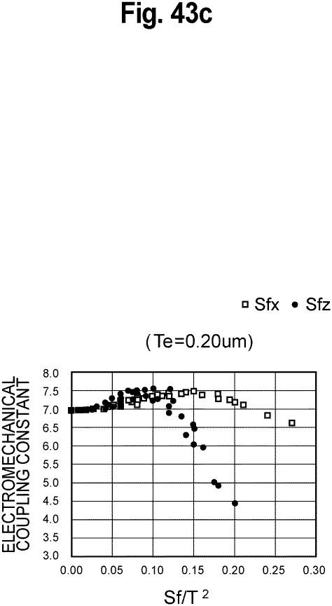

In the examples shown in FIGS. 43(a) to 43(c), cases are explained in which the thickness T of the crystal piece 11, the thickness Te of the flat plate portion 14B of the excitation electrode unit 14, and the thickness Tf of the thick film portion 14C of the excitation electrode unit 14 are changed as various parameters related to the crystal oscillation element 10. The thickness Tf corresponds to the protrusion amount of the thick film portion 14C from the flat plate portion 14B of the excitation electrode unit 14. FIG. 43(a) is a graph related to the case where the ratio of the thickness Te of the flat plate portion 14B of the excitation electrode unit 14 to the thickness T of the crystal piece 11 is “0.05”. FIG. 43(b) is a graph related to the case where the ratio of the thickness Te of the flat plate portion 14B of the excitation electrode unit 14 to the thickness T of the crystal piece 11 is “0.10”. FIG. 43(c) is a graph related to the case where the ratio of the thickness Te of the flat plate portion 14B of the excitation electrode unit 14 to the thickness T of the crystal piece 11 is “0.20”. In any of these examples, in the case where the condition regarding the ratio of the cross-sectional area of the first protruding portion 14Ca that maximizes the electromechanical coupling constant is compared with the condition regarding the ratio of the cross-sectional area of the second protruding portion 14Cb that maximizes the electromechanical coupling constant, the cross-sectional area of the first protruding portion 14Ca is larger than the cross-sectional area of the second protruding portion 14Cb.

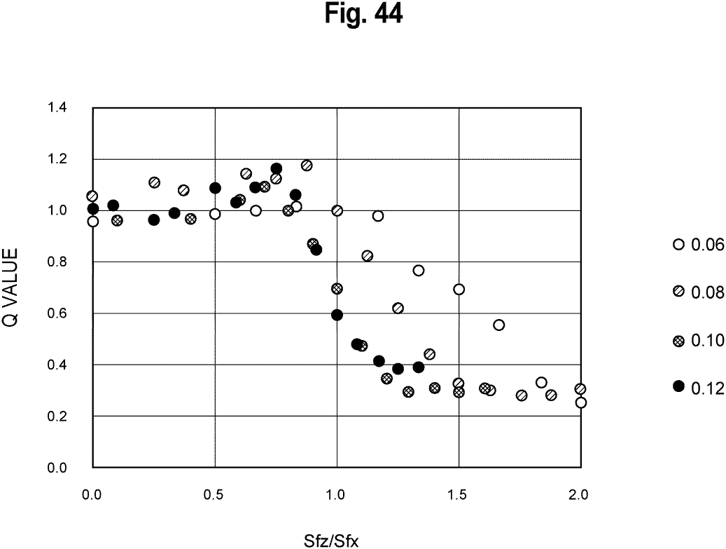

The example shown in FIG. 44 illustrates the transition of a change in a Q value, which is a parameter indicating the state of vibrations of the crystal oscillator 1, when changing the ratio of the cross-sectional area Sfz of the second protruding portion 14Cb to the cross-sectional area Sfx of the first protruding portion 14Ca of the excitation electrode unit 14. In this example, a graph is shown for the cases where the ratio of the cross-sectional area Sfx of the first protruding portion 14Ca of the excitation electrode unit 14 to the thickness T of the crystal piece 11 is “0.06”, “0.08”, “0.10”, and “0.12”. In this graph, in any of the cases, when the value of Sfz/Sfx exceeds “1.0”, the Q value drops sharply. That is, when the cross-sectional area Sfz of the second protruding portion 14Cb of the excitation electrode unit 14 becomes larger than the cross-sectional area Sfx of the first protruding portion 14Ca, the Q value drops sharply. Therefore, by making the cross-sectional area Sfx of the first protruding portion 14Ca of the excitation electrode unit 14 larger than the cross-sectional area Sfz of the second protruding portion 14Cb, the vibration characteristic of the crystal oscillation element 10 can be improved.

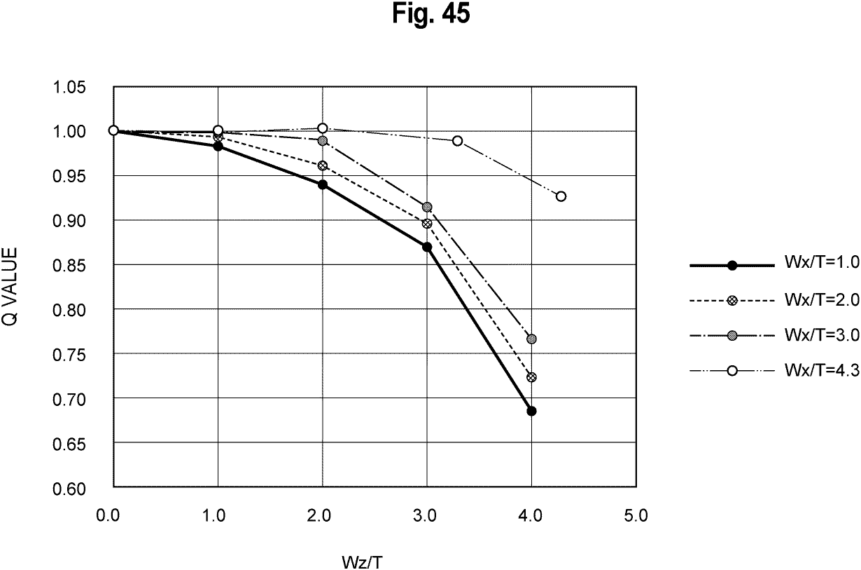

The example shown in FIG. 45 illustrates the transition of a change in the Q value, which is a parameter indicating the state of vibrations of the crystal oscillator 1, when changing the ratio of the width Wz of the second protruding portion 14Cb of the excitation electrode unit 14 to the thickness T of the crystal piece 11. In this example, a graph is shown for the cases where the ratio of the width Wx of the first protruding portion 14Ca of the excitation electrode unit 14 to the thickness T of the crystal piece 11 is “1.0”, “2.0”, “3.0”, and “4.3”. In this graph, in any of the cases, when the width Wz of the second protruding portion 14Cb of the excitation electrode unit 14 is larger than the width Wx of the first protruding portion 14Ca, the Q value drops sharply. Therefore, by making the width Wx of the first protruding portion 14Ca of the excitation electrode unit 14 larger than the width Wz of the second protruding portion 14Cb, the vibration characteristic of the crystal oscillation element 10 can be improved.

Exemplary modes of the present invention are described below, and effects thereof are also described. However, it should be appreciated that the exemplary aspects of the present invention are not limited to the following additions.

According to an exemplary aspect, a crystal oscillation element is provided that comprises a crystal piece having principal planes defined by a first base axis and a second base axis that intersects the first base axis, and an excitation electrode unit at the principal planes of the crystal piece. In this aspect, when a voltage is applied to the excitation electrode unit, the crystal piece performs thickness-shear vibrations by vibrating in a plane defined by a thickness direction and the first base axis, the thickness direction being a direction intersecting the principal planes, the excitation electrode unit has flat plate portions and thick film portions that are located at electrode ends on the principal planes of the crystal piece and that have a thickness larger than that of the flat plate portions, the thick film portion has first protruding portions as protruding portions that are located at the ends in the axis direction of the first base axis on the principal plane, extend in the axis direction of the second base axis and protrude from the flat plate portion, and second protruding portions as protruding portions that are located at the ends in the axis direction of the second base axis on the principal plane, extend in the axis direction of the first base axis and protrude from the flat plate portion. Moreover, a cross-sectional area of the first protruding portion cut in a direction along a plane defined by the first base axis and the thickness direction of the crystal piece is larger than a cross-sectional area of the second protruding portion cut in a direction along a plane defined by the second base axis and the thickness direction of the crystal piece.

According to another exemplary aspect of, the crystal oscillation element, the material of the first protruding portions and the second protruding portions is aluminum, and the maximum value of the cross-sectional areas of the first protruding portion and the second protruding portion at which a vibration characteristic of the crystal oscillation element satisfies a predetermined condition increases as the ratio of the thickness of the flat plate portion to the thickness of the crystal piece increases.

According to another exemplary aspect of the crystal oscillation element, the maximum value of the cross-sectional areas of the first protruding portion and the second protruding portion at which the vibration characteristic of the crystal oscillation element satisfies the predetermined condition is represented by a linear function with the ratio of the thickness of the flat plate portion to the thickness of the crystal piece as a variable.

According to another exemplary aspect of the crystal oscillation element, the width of the first protruding portion in a direction intersecting the protrusion direction of the first protruding portion is larger than the width of the second protruding portion in a direction intersecting the protrusion direction of the second protruding portion.

According to another exemplary aspect of the crystal oscillation element, the material of the first protruding portions and the second protruding portions is aluminum, and the maximum value of the width of the first protruding portion and the second protruding portion at which a vibration characteristic satisfies a predetermined condition increases as the ratio of the thickness of the flat plate portion to the thickness of the crystal piece increases.

According to another exemplary aspect of the crystal oscillation element, the maximum value of the width of the first protruding portion and the second protruding portion at which the vibration characteristic satisfies the predetermined condition is represented by a linear function with the ratio of the thickness of the flat plate portion to the thickness of the crystal piece as a variable.

According to another exemplary aspect of the crystal oscillation element, the protrusion amount of the first protruding portion is larger than the protrusion amount of the second protruding portion.

According to another exemplary aspect, a crystal oscillation element is provided that comprise a crystal piece having principal planes defined by a first base axis and a second base axis that intersects the first base axis, and an excitation electrode unit provided at the principal planes of the crystal piece. In this aspect, when a voltage is applied to the excitation electrode unit, the crystal piece performs thickness-shear vibrations by vibrating in a plane defined by a thickness direction and the first base axis, where the thickness direction is a direction intersecting the principal planes. In addition, the excitation electrode unit has flat plate portions and thick film portions that are located at electrode ends on the principal planes of the crystal piece and that have a thickness larger than that of the flat plate portions, and the thick film portion has first protruding portions as protruding portions that are located at the ends in the axis direction of the first base axis on the principal plane and extend in the axis direction of the second base axis.

According to another exemplary aspect, a crystal oscillation element is provided that comprises a crystal piece having principal planes defined by a first base axis and a second base axis that intersects the first base axis, and an excitation electrode unit provided at the principal planes of the crystal piece. In this aspect, when a voltage is applied to the excitation electrode unit, the crystal piece performs thickness-shear vibrations by vibrating in a plane defined by a thickness direction and the first base axis, where the thickness direction is a direction intersecting the principal planes. Moreover, the excitation electrode unit has flat plate portions and thick film portions that are located at electrode ends on the principal planes of the crystal piece and that have a thickness larger than that of the flat plate portions, and the thick film portion has second protruding portions as protruding portions that are located at the ends in the axis direction of the second base axis on the principal plane and extend in the axis direction of the first base axis.

According to another exemplary aspect of the crystal oscillation element, where an axis obtained by tilting the third axis, among a first axis, a second axis, and a third axis that are crystallographic axes of the crystal piece and intersect each other, at a predetermined angle about the first axis is taken as a third tilted axis, the first axis is made to correspond to the first base axis and the third tilted axis is made to correspond to the second base axis.

According to another exemplary aspect of the crystal oscillation element, where an axis obtained by tilting the first axis, among a first axis, a second axis, and a third axis that are crystallographic axes of the crystal piece and intersect each other, at a predetermined angle about the third axis is taken as a first tilted axis, and an axis obtained by tilting the third axis at a predetermined angle about the first axis is taken as a third tilted axis, the first axis is made to correspond to the first base axis and the third tilted axis is made to correspond to the second base axis.

According to another exemplary aspect of the crystal oscillation element, the protruding portions are made of the same material as the flat plate portions in the excitation electrode unit.

According to another exemplary aspect of the crystal oscillation element, the protruding portions are made of a material different from that of the flat plate portions in the excitation electrode unit.

According to another exemplary aspect of the crystal oscillation element, the protruding portions are made of an insulating material.

As described above, according to exemplary embodiments of the present invention, spurious oscillations are reduced.

In general, it is noted that the embodiments described above are intended to facilitate the understanding of the present invention, and are not intended to limit or interpret the present invention. The present invention may be changed/modified without departing from the spirit thereof, and the present invention also includes equivalents thereof. In other words, the scope of the present invention is also inclusive of any embodiment subjected, as appropriate, by a person skilled in the art to a design change as long as specific features of the present invention are included. For example, elements provided in each embodiment and arrangement, material, condition, shape, size, and the like thereof are not limited to those illustrated and can be changed as appropriate. Moreover, elements provided in the embodiments can be combined as long as it is technically possible, and combinations thereof are also included in the scope of the present invention as long as specific features of the present invention are included.

REFERENCE SIGNS LIST

| | |
|---|---|
| 1 | Crystal oscillator |
| 10 | Crystal oscillation element |
| 11 | Crystal piece |
| 14a, 14b | Excitation electrodes |
| 15a, 15b | Lead-out electrodes |
| 16a, 16b | Connection electrodes |
| 30 | Base member |
| 33a, 33b | Electrode pads |
| 34a, 34b | Through electrodes |
| 35a to 35d | External electrodes |
| 36a, 36b | Conductive holding member |
| 40 | Lid member |
| 50 | Joining member |

What is claimed is:

1. A crystal oscillation element comprising:
a crystal piece having principal planes defined by a first base axis and a second base axis that intersects the first base axis; and
an excitation electrode unit at the principal planes of the crystal piece and having flat plate portions and thick film portions that are located at electrode ends on the principal planes of the crystal piece and that have a thickness larger than a thickness of the flat plate portions,
wherein each thick film portion has first protruding portions located at the electrodes ends in an axis direction of the first base axis on the principal plane, extend in an axis direction of the second base axis and protrude from the flat plate portion, and second protruding portions located at the electrodes ends in the axis direction of the second base axis on the principal plane, extend in the axis direction of the first base axis and protrude from the flat plate portion, and
wherein the first protruding portion has a cross-sectional area cut in a direction along a plane defined by the first base axis and a thickness direction of the crystal piece that is larger than a cross-sectional area of the second protruding portion cut in a direction along a plane defined by the second base axis and the thickness direction of the crystal piece.

2. The crystal oscillation element according to claim 1, wherein, when a voltage is applied to the excitation electrode unit, the crystal piece is configured to perform thickness-shear vibrations by vibrating in a plane defined by the thickness direction and the first base axis, where the thickness direction intersects the principal planes.

3. The crystal oscillation element according to claim 1, wherein the first protruding portions and the second protruding portions comprise aluminum, and a maximum value of the cross-sectional area of each of the first protruding portion and the second protruding portion at which a vibration characteristic of the crystal oscillation element satisfies a predetermined condition increases as the ratio of the thickness of the flat plate portion to the thickness of the crystal piece increases.

4. The crystal oscillation element according to claim 3, wherein the maximum value of the cross-sectional area of each of the first protruding portion and the second protruding portion at which the vibration characteristic of the crystal oscillation element satisfies the predetermined condition is represented by a linear function with the ratio of the thickness of the flat plate portion to the thickness of the crystal piece as a variable.

5. The crystal oscillation element according to claim 1, wherein a width of the first protruding portion is larger than a width of the second protruding portion.

6. The crystal oscillation element according to claim 5, wherein the first protruding portions and the second protruding portions comprise aluminum, and a maximum value of the width of the first protruding portion and the second protruding portion at which a vibration characteristic satisfies a predetermined condition increases as the ratio of the thickness of the flat plate portion to the thickness of the crystal piece increases.

7. The crystal oscillation element according to claim 6, wherein the maximum value of the width of the first protruding portion and the second protruding portion at which the vibration characteristic satisfies the predetermined condition is represented by a linear function with the ratio of the thickness of the flat plate portion to the thickness of the crystal piece as a variable.

8. The crystal oscillation element according to claim 1, wherein a protrusion amount of the first protruding portion is larger than a protrusion amount of the second protruding portion.

9. The crystal oscillation element according to claim 1, wherein, where an axis obtained by tilting a third axis, among a first axis, a second axis, and a third axis that are crystallographic axes of the crystal piece and intersect each other, at a predetermined angle about the first axis is taken as a third tilted axis, the first axis corresponds to the first base axis and the third tilted axis corresponds to the second base axis.

10. The crystal oscillation element according to claim 1, wherein, where an axis obtained by tilting a first axis, among a first axis, a second axis, and a third axis that are crystallographic axes of the crystal piece and intersect each other, at a predetermined angle about the third axis is taken as a first tilted axis, and an axis obtained by tilting the third axis at a predetermined angle about the first axis is taken as a third tilted axis, the first axis corresponds to the first base axis and the third tilted axis corresponds to the second base axis.

11. The crystal oscillation element according to claim 1, wherein the protruding portions comprise a same material as the flat plate portions in the excitation electrode unit.

12. The crystal oscillation element according to claim 1, wherein the protruding portions comprise a material different from that of the flat plate portions in the excitation electrode unit.

13. The crystal oscillation element according to claim 1, wherein the protruding portions comprise an insulating material.

14. A crystal oscillator comprising:
the crystal oscillation element according to claim 1;
a base on which the crystal oscillation element is mounted; and
a lid joined to the base to seal the crystal oscillation element.

15. A crystal oscillation element comprising:
a crystal piece having principal planes defined by a first base axis and a second base axis that intersects the first base axis; and
an excitation electrode unit at the principal planes of the crystal piece and having flat plate portions and thick film portions that are located at electrode ends on the principal planes of the crystal piece and that have a thickness larger than a thickness of the flat plate portions,
wherein each thick film portion has protruding portions located at the electrode ends in an axis direction of the first base axis on the principal plane and extend in an axis direction of the second base axis.

16. The crystal oscillation element according to claim 15, wherein, when a voltage is applied to the excitation electrode unit, the crystal piece is configured to perform thickness-shear vibrations by vibrating in a plane defined by a thickness direction and the first base axis, where the thickness direction intersects the principal planes.

17. The crystal oscillation element according to claim 15, wherein the protruding portions comprise an insulating material.

18. A crystal oscillation element comprising:
a crystal piece having principal planes defined by a first base axis and a second base axis that intersects the first base axis; and
an excitation electrode unit at the principal planes of the crystal piece and having flat plate portions and thick film portions that are located at electrode ends on the principal planes of the crystal piece and that have a thickness larger than a thickness of the flat plate portions,
wherein each thick film portion has protruding portions that are located at the electrode ends in an axis direction of the second base axis on the principal plane and extend in an axis direction of the first base axis.

19. The crystal oscillation element according to claim 18, wherein, when a voltage is applied to the excitation electrode unit, the crystal piece is configured to perform thickness-shear vibrations by vibrating in a plane defined by a thickness direction and the first base axis, where the thickness direction intersects the principal planes.

20. The crystal oscillation element according to claim 18, wherein the protruding portions comprise an insulating material.
